(19) United States
(12) Patent Application Publication
(10) Pub. No.: US 2024/0423042 A1
(43) Pub. Date: Dec. 19, 2024

(54) DISPLAY DEVICE AND DISPLAY PANEL

(71) Applicant: LG Display Co., Ltd., Seoul (KR)

(72) Inventors: JoungMi Choi, Paju-si (KR); EuiHyun Chung, Paju-si (KR); Hyunguk Jang, Paju-si (KR)

(73) Assignee: LG Display Co., Ltd., Seoul (KR)

(21) Appl. No.: 18/742,282

(22) Filed: Jun. 13, 2024

(30) Foreign Application Priority Data
Jun. 16, 2023 (KR) 10-2023-0077636

(51) Int. Cl. H10K 59/131; H10K 59/121

(52) U.S. Cl. CPC H10K 59/131; H10K 59/1213

(57) ABSTRACT

A display device according to one or more examples may include a substrate, a pixel array layer located on the substrate and including a plurality of subpixels disposed in a display area where an image is displayed, and a base circuit layer located between the substrate and the pixel array layer and including a gate driving circuit disposed over the entire display area. A display panel and a display apparatus are also disclosed.

### CROSS REFERENCE TO RELATED APPLICATION

This application claims the benefit of and priority to Korean Patent Application No. 10-2023-0077636, filed on Jun. 16, 2023, which is hereby incorporated by reference for all purposes as if fully set forth herein.

### BACKGROUND

### 1. Technical Field

Embodiments of the present disclosure relate to display apparatuses, and particularly to, for example, without limitation, a display device and a display panel.

### 2. Description of the Related Art

A display device may include a display panel on which a plurality of data lines and a plurality of gate lines are arranged, a data driving circuit for driving the plurality of data lines, and a gate driving circuit for driving the plurality of gate lines. Here, the display panel may include a display area where an image is displayed and a non-display area where the image is not displayed.

In the case of a general display device, a gate driving circuit may be connected to or disposed in a non-display area (also referred to as a bezel) of the display panel. Accordingly, it is not easy to reduce a size of the non-display area (e.g., bezel) of the display panel.

The description of the related art should not be assumed to be prior art merely because it is mentioned in or associated with this section. The description of the related art may include information that describes one or more aspects of the subject technology, and the description in this section does not limit the invention.

### SUMMARY

The inventors of the present disclosure have recognized the problems and disadvantages of the related art and have performed extensive research and experiments. The inventors of the present disclosure have thus invented a new display device and a new display panel that substantially obviate one or more problems due to limitations and disadvantages of the related art.

One or more example embodiments of the present disclosure may provide a display panel and a display device in which a gate driving circuit is arranged over the entire display area.

One or more example embodiments of the present disclosure may provide a display panel and a display device in which a gate driving circuit is arranged to overlap a pixel array layer in a vertical direction.

One or more example embodiments of the present disclosure may provide a display panel and a display device having a structure capable of shielding an electric field between a base circuit layer where a gate driving circuit is disposed and a pixel array layer where the subpixel are disposed.

One or more example embodiments of the present disclosure may provide a display panel and a display device having an extremely narrow bezel structure.

A display device according to one or more example embodiments of the present disclosure may include a substrate, a pixel array layer located on the substrate and including a plurality of subpixels disposed in a display area where an image is displayed, and a base circuit layer located between the substrate and the pixel array layer and including a gate driving circuit disposed over the entire display area.

The base circuit layer may include two or more power lines which are disposed in the display area, and to which two or more common pixel driving voltages supplied to the pixel array layer are applied.

A display device according to one or more example embodiments of the present disclosure may further include a shielding layer located between the base circuit layer and the pixel array layer.

The shielding layer may be electrically connected to a metal disposed on the pixel array layer.

For example, the shielding layer may be electrically connected to a source electrode or a drain electrode of one of a plurality of pixel driving transistors disposed in the pixel array layer, or may be electrically connected to a first driving voltage line disposed on the pixel array layer.

As another example, the shielding layer may be electrically connected to a common electrode among the pixel electrodes and common electrodes included in a light emitting device disposed in the pixel array layer, or may be electrically connected to a second driving voltage line disposed in the pixel array layer.

The shielding layer may be electrically connected to a metal located in the base circuit layer.

The base circuit layer may include two or more power lines which are disposed in the display area, and to which two or more common pixel driving voltages supplied to the pixel array layer are applied.

The shielding layer may be electrically connected to one of the two or more power lines.

As an example, the shielding layer may be electrically connected to a first power line to which the first driving voltage VDD is applied among two or more power lines.

As another example, the shielding layer may be electrically connected to a second power line to which a second driving voltage VSS is applied among two or more power lines.

The shielding layer may electrically connect a metal located in the pixel array layer and a metal located in the base circuit layer.

The base circuit layer may include a gate driving transistor including a first active layer, and the pixel array layer may include a pixel driving transistor including a second active layer. The first active layer and the second active layer may include different semiconductor materials.

The base circuit layer may include an organic layer disposed on a plurality of gate driving transistors included in the gate driving circuit.

A display panel according to one or more example embodiments of the present disclosure may include a substrate, a pixel array layer located on the substrate and including a plurality of subpixels disposed in a display area where an image is displayed, a base circuit layer located between the substrate and the pixel array layer and on, at or in which a gate driving circuit is disposed, and a shielding layer located between the base circuit layer and the pixel array layer.

The base circuit layer may include an organic layer disposed on a gate driving transistor included in the gate driving circuit.

The base circuit layer may include two or more power lines to which two or more common pixel driving voltages supplied to the pixel array layer are applied.

The shielding layer may electrically connect a metal disposed in the pixel array layer and a metal disposed in the base circuit layer.

A display apparatus according to one or more example embodiments of the present disclosure may include a substrate, a pixel array layer disposed on the substrate and including a plurality of subpixels disposed in a display area in which an image is to be displayed, and a base circuit layer disposed between the substrate and the pixel array layer and including a driving circuit. The plurality of subpixels may include pixel driving transistors. The driving circuit may include transistors. One or more of the transistors in the base circuit layer may be coupled to respective one or more of the pixel driving transistors in the pixel array layer.

The base circuit layer may include one or more power lines coupled to at least one of the plurality of subpixels. The driving circuit of the base circuit layer may include gate driving transistors.

According to one or more example embodiments of the present disclosure, there may provide a display panel and a display device in which a gate driving circuit is arranged over the entire display area. Accordingly, it is possible to significantly reduce a bezel size of the display panel.

According to one or more example embodiments of the present disclosure, there may provide a display panel and a display device in which a gate driving circuit is arranged to overlap a pixel array layer in a vertical direction, thereby significantly reducing a bezel size of the display panel.

According to one or more example embodiments of the present disclosure, there may provide a display panel and a display device having a structure capable of shielding an electric field between a base circuit layer where a gate driving circuit is disposed and a pixel array layer where the subpixel are disposed. Accordingly, it is possible to eliminate unnecessary electrical influence between the base circuit layer and the pixel array layer.

According to one or more example embodiments of the present disclosure, there may provide a display panel and a display device in which a gate driving circuit and various power lines are disposed in a display area. Accordingly, an extremely narrow bezel structure of the display panel may be possible.

According to one or more example embodiments of the present disclosure, the base circuit layer on which the gate driving circuit and various power lines are arranged may be arranged to overlap the pixel array layer in the vertical direction, so that a length of a path through which the gate signal output from the gate driving circuit is supplied to the pixel array layer can be shortened, and a length of a path through which a power (e.g., pixel driving voltage) output from various power lines is supplied to the pixel array layer can be shortened. Accordingly, it is possible to reduce the metal used in the supply path, and thus is possible to reduce the weight of display panels and display devices.

Additional features, advantages, embodiments and aspects of the present disclosure are set forth in part in the description that follows and in part will become apparent from the present disclosure or may be learned by practice of the inventive concepts provided herein. Other features, advantages, embodiments and aspects of the present disclosure may be realized and attained by the descriptions provided in the present disclosure, or derivable therefrom, and the claims hereof as well as the appended drawings. It is intended that all such features, advantages, embodiments and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a system configuration diagram of a display device according to one or more example embodiments of the present disclosure.

FIG. 2 illustrates a display panel according to one or more example embodiments of the present disclosure.

FIG. 3 illustrates a stacked structure of a display panel according to one or more example embodiments of the present disclosure.

FIG. 4 illustrates another example of a stacked structure of a display panel according to one or more example embodiments of the present disclosure.

FIG. 5 illustrates a plurality of unit areas constituting a base circuit layer within a display area of a display panel according to one or more example embodiments of the present disclosure.

FIG. 6 illustrates a structure of a first unit area among a plurality of unit areas constituting a base circuit layer in the display area of a display panel according to one or more example embodiments of the present disclosure.

FIG. 7 illustrates an equivalent circuit of a subpixel in a display panel according to one or more example embodiments of the present disclosure.

FIG. 8 illustrates an example of a structure of a first unit area among a plurality of unit areas in the base circuit layer within the display area of the display panel according to one or more example embodiments of the present disclosure.

FIG. 9 illustrates an example of a structure of one driving line area in the base circuit layer within the display area of the display panel according to one or more example embodiments of the present disclosure.

FIG. 10 illustrates an example of first blocks in two driving line areas in the base circuit layer within the display area of the display panel according to one or more example embodiments of the present disclosure.

FIG. 11 is a diagram illustrating a vertical correspondence structure between a base circuit layer and a pixel array layer in a display area of a display panel according to one or more example embodiments of the present disclosure.

FIG. 12 is another diagram illustrating a vertical correspondence structure between a base circuit layer and a pixel array layer in a display area of a display panel according to one or more example embodiments of the present disclosure.

FIG. 13 is a diagram briefly illustrating a gate driving circuit according to one or more example embodiments of the present disclosure.

FIG. 14 is a cross-sectional view of a display area of a display panel according to one or more example embodiments of the present disclosure.

FIG. 15 is another cross-sectional view of the display area of a display panel according to one or more example embodiments of the present disclosure.

FIG. 16 is a plan view of a display panel according to one or more example embodiments of the present disclosure.

FIG. 17 illustrates a general area and a first type optical area included in the display area of a display panel according to one or more example embodiments of the present disclosure.

FIG. 18 illustrates a general area and a second type of optical area included in the display area of a display panel according to one or more example embodiments of the present disclosure.

FIG. 19 is a cross-sectional view of an optical area within a display area of a display panel according to one or more example embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate (ly),” “direct (ly),” or “close (ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate (ly),” or “direct (ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, bor c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” may apply, for example, to a separate circuit or structure, an integrated circuit, a computational block of a circuit device, or any structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

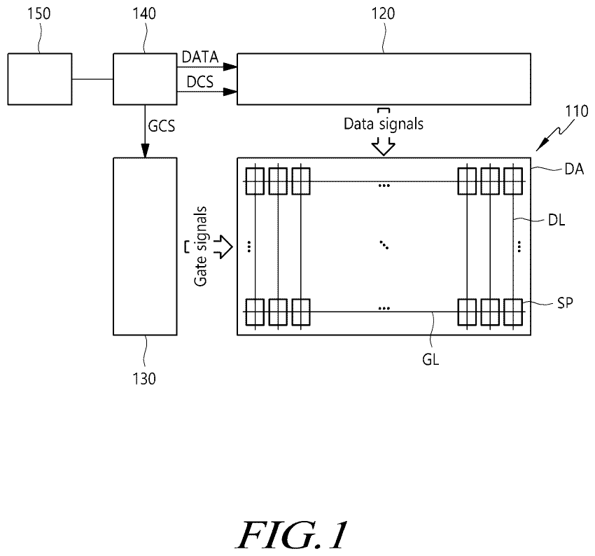

FIG. 1 is a system configuration diagram of a display device 100 according to one or more example embodiments of the present disclosure.

Referring to FIG. 1, a display device 100 according to one or more example embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a display area DA where an image is displayed.

The display panel 110 may not have a non-display area located outside the display area DA, or may include only a very small non-display area. For example, even if the display panel 110 includes a non-display area, the boundary area between the display area and the non-display area may be bent so that the non-display area may be located below the display area. In this case, when the user looks at the display device 100 from the front, there may be little or no non-display area visible to the user.

The display panel 110 may include a plurality of subpixels SP and various types of signal lines to drive the plurality of subpixels SP.

The display device 100 according to one or more example embodiments of the present disclosure may be a liquid crystal display device or the like, or may be a self-luminous display device in which the display panel 110 emits light by itself. When the display device 100 according to one or more example embodiments of the present disclosure is a self-luminous display device, each of the plurality of subpixels SP may include a light emitting device.

For example, the display device 100 according to one or more example embodiments of the present disclosure may be an organic light emitting display device in which a light emitting device is implemented as an organic light emitting diode (OLED). For another example, the display device 100 according to one or more example embodiments of the present disclosure may be an inorganic light emitting display device in which the light emitting device is implemented as an inorganic-based light emitting diode. For another example, the display device 100 according to one or more example embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

The plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, and so on, the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to one or more example embodiments of the present disclosure, the gate driving circuit 130 may be disposed to overlap the display area DA of the display panel 110. For example, the gate driving circuit 130 may be disposed over the entire display area DA, or may be disposed only on a portion (e.g., both sides) of the display area DA. In the case that the gate driving circuit 130 is arranged to overlap the display area DA, the gate driving circuit 130 may be arranged not to overlap the subpixels SP, or may be arranged to partially or completely overlap the subpixels SP.

In the display device 100 according to one or more example embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 220 to control the data driving circuit 120, and may supply a gate driving control signal GCS to the gate driving circuit 230 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, or another component, and may be electrically connected to the data driving circuit 120 and the gate driving circuit 130 through a printed circuit board, a flexible printed circuit, or another component.

The display controller 240 may transmit and receive signals with the data driving circuit 220 according to one or more predetermined interfaces. For example, the interface may include a low voltage differential signaling (LVDS) interface, an embedded clock point-point interface (EPI) interface, or a serial peripheral interface (SPI).

In order to provide not only an image display function but also a touch sensing function, the display device 100 according to one or more example embodiments of the present disclosure may include a touch sensor and a touch sensing circuit for detecting an occurrence of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate SUB along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, or another object). According to the self-capacitance sensing method, each of the plurality of touch electrodes may serve as a driving touch electrode and a sensing touch electrode. The touch driving circuit 260 may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit 260 and the data driving circuit 220 may be implemented as separate devices or as one device.

The display device 100 may further include a power supply circuit which supplies various types of power to the display driving circuit and/or the touch sensing circuit.

The display device 100 according to one or more example embodiments of the present disclosure may be a mobile terminal such as a smart phone or tablet, or a monitor or television of various sizes, but is not limited thereto, and may be a display of various types and sizes capable of displaying information or images.

The display device 100 according to one or more example embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

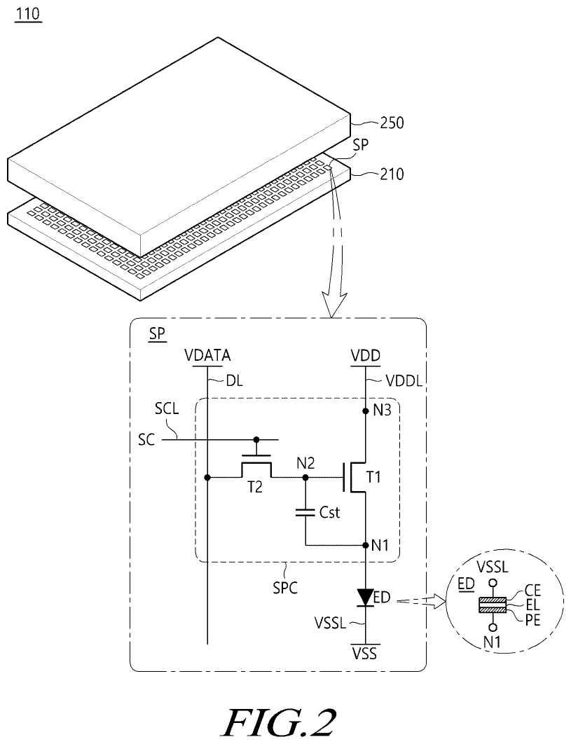

FIG. 2 illustrates a display panel 110 according to one or more example embodiments of the present disclosure.

Referring to FIG. 2, the display panel 110 may include a substrate 210 disposed in a plurality of subpixels SP and an encapsulation layer 250 on the substrate 210. Here, the encapsulation layer 250 may also be referred to as an encapsulation substrate or an encapsulation portion.

Referring to FIG. 2, when the display device 100 according to one or more example embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED.

The plurality of pixel driving transistors may include a first transistor T1 which is a driving transistor for driving the light emitting device ED, and a second transistor T2 for transmitting a data signal VDATA to a second node N2 of the first transistor T1.

At least one capacitor may include a storage capacitor Cst to maintain a constant voltage during the frame.

A data signal VDATA which is an image signal, and a scan signal SC which is a gate signal may be applied to the subpixel SP in order to drive the subpixel SP. In addition, in order to drive the subpixel SP, a common pixel driving voltage including the first driving voltage VDD and the second driving voltage VSS may be applied to the subpixel SP.

The light emitting device ED may include a pixel electrode PE, a device intermediate layer EL, and a common electrode CE. The pixel electrode PE may be an electrode disposed in each subpixel SP, and the common electrode CE may be an electrode commonly disposed in a plurality of subpixels SP. The device intermediate layer EL may be a layer disposed between the pixel electrode PE and the common electrode CE, and may include an emission layer EML.

In the case that the light emitting device ED is an organic light emitting device, the device intermediate layer EL may include an emission layer EML, a first common layer between an anode and the emission layer, and a second common layer between the emission layer and the cathode. The emission layer may be disposed in each subpixel SP, and the first and second common layers may be commonly disposed in a plurality of subpixels SP. The emission layer may be disposed in each emission area, and the first common layer and the second common layer may be commonly disposed across a plurality of emission areas and non-emission areas. Here, the anode may be a pixel electrode PE or a common electrode CE, and the cathode may be a common electrode CE or a pixel electrode PE.

The first common layer may include a hole injection layer HIL and a hole transport layer HTL, and the second common layer may include an electron transport layer ETL and an electron injection layer EIL. The hole injection layer may inject holes from the anode to the hole transport layer, the hole transport layer may transport holes to the emission layer, the electron injection layer may inject electrons from the cathode to the electron transport layer, and the electron transport layer may transport electrons to the emission layer.

For example, the common electrode CE may be electrically connected to a second driving voltage line VSSL. The second driving voltage VSS, which is a type of common pixel driving voltage, may be applied to the common electrode CE through the second driving voltage line VSSL. The pixel electrode PE may be electrically connected to a first node N1 of the first transistor T1 of each subpixel SP.

For example, the pixel electrode PE may be an anode, and the common electrode CE may be a cathode. Alternatively, the pixel electrode PE may be a cathode, and the common electrode CE may be an anode. Hereinafter, for convenience of explanation, it is assumed that the pixel electrode PE is an anode and the common electrode CE is a cathode.

Each light emitting device ED may include overlapping parts of a pixel electrode PE, a device intermediate layer EL and a common electrode CE. A predetermined emission area may be formed by each light emitting device ED. For example, the emission area of each light emitting device ED may include an area where the pixel electrode PE, the device intermediate layer EL and the common electrode CE overlap.

For example, the light emitting device ED may be an organic light emitting diode (OLED), an inorganic light emitting diode, or a quantum dot light emitting device. For example, if the light emitting device ED is an organic light emitting diode OLED, the device intermediate layer EL in the light emitting device ED may include an organic device intermediate layer EL containing an organic material.

The first transistor T1 may be a driving transistor for supplying driving current to the light emitting device ED. The first transistor T1 may be connected between the first driving voltage line VDDL and the light emitting device ED.

The first transistor T1 may include a first node N1 electrically connected to the light emitting device ED, a second node N2 to which the data signal VDATA is be applied, and a third node N3 to which the driving voltage VDD is applied from the driving voltage line DVL.

In the first transistor T1, the second node N2 may be a gate node, the first node N1 may be a source node or a drain node, and the third node N3 may be a drain node or a source node. Hereinafter, for convenience of explanation, it will be exemplified a case in which the second node N2 is a gate node, the first node N1 is a source node and the third node N3 is a drain node in the first transistor T1.

The second transistor T2 may be a switching transistor for transmitting the data signal VDATA, which is an image signal, to the second node N2 as the gate node of the first transistor T1 as the driving transistor.

The second transistor T2 may be controlled to be turned on or off by a scan signal SC, which is a gate signal applied through a scan line SCL as a type of gate line GL, to control the electrical connection between the second node N2 of the first transistor T1 and the data line DL. The drain electrode or source electrode of the second transistor T2 may be electrically connected to the data line DL, and a source electrode or drain electrode of the second transistor T2 may be connected to the second node N2 of the first transistor T1, and agate electrode of the second transistor T2 may be electrically connected to the scan line SCL.

The storage capacitor Cst may be electrically connected between the first node N1 and the first node N2 of the first transistor T1. The storage capacitor Cst may include a first capacitor electrode electrically connected to the first node N1 of the first transistor T1 or corresponding to the first node N1 of the first transistor T1, and a second capacitor electrode electrically connected to the second node N2 of the first transistor T1 or corresponding to the second node N2 of the first transistor T1.

The storage capacitor Cst may be an external capacitor intentionally designed outside the driving transistor Ta rather than a parasitic capacitor (e.g., Cgs, Cgd) as an internal capacitor which may exist between the first node N1 and the second node N2 of the driving transistor T1.

Each of the driving transistor T1 and the scan transistor T2 may be an n-type transistor or a p-type transistor.

At least a portion of the subpixel circuit SPC may overlap with at least a portion of the light emitting device ED in a vertical direction. Alternatively, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some case, Depending on this, the subpixel circuit SPC may further include one or more transistors or one or more capacitors.

For example, the subpixel circuit SPC may have a 6T-1C structure including six transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 250 may be disposed on the display panel 110 to prevent oxygen from penetrating into the circuit elements (particularly, the light emitting device ED). The encapsulation layer 250 may be configured in various shapes to prevent the light emitting device ED from coming into contact with moisture or oxygen.

The display device 100 according to one or more example embodiments of the present disclosure may have an extremely narrow bezel structure in which the non-display area of the display panel 110 is very small or almost absent. Hereinafter, an extremely narrow bezel structure of the display panel 110 of the display device 100 is described according to one or more example embodiments of the present disclosure.

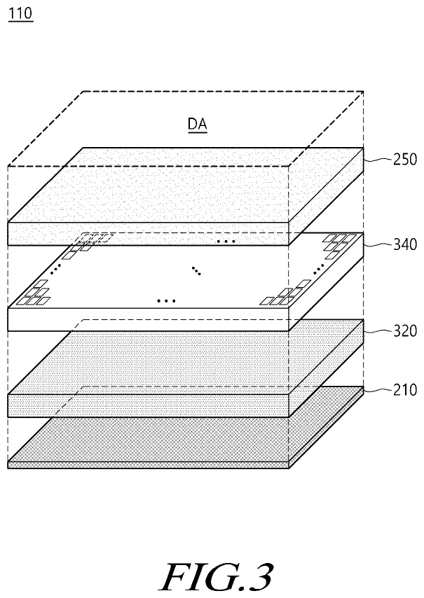

FIG. 3 illustrates a stacked structure of a display panel 110 according to one or more example embodiments of the present disclosure.

Referring to FIG. 3, the display panel 110 according to one or more example embodiments of the present disclosure may include a substrate 210, a base circuit layer 320, a pixel array layer 340, and an encapsulation layer 250.

Referring to FIG. 3, the pixel array layer 340 may be a layer in which a plurality of subpixels SP are formed, and may be located on the substrate 210. The pixel array layer 340 may include a plurality of subpixels SP disposed in a display area DA where an image is displayed.

Referring to FIG. 3, the base circuit layer 320 may be a layer in which a gate driving circuit 130 is formed as a gate-in-panel type, and may be located between the substrate 210 and the pixel array layer 340. The base circuit layer 320 may include a gate driving circuit 130 of a gate-in-panel type.

For example, the base circuit layer 320 may include a gate driving circuit 130 disposed throughout the display area DA. For another example, the base circuit layer 320 may include a gate driving circuit 130 disposed in at least one partial area of the display area DA. Hereinafter, it will be described as an example a case where the gate driving circuit 130 included in the base circuit layer 320 is disposed over the entire display area DA.

Referring to FIG. 3, the base circuit layer 320 may be a layer in which two or more power lines are formed to which two or more common pixel driving voltages supplied to the pixel array layer 340 are applied. That is, the base circuit layer 320 may further include two or more power lines to which two or more common pixel driving voltages supplied to the pixel array layer 340 are applied.

For example, two or more common pixel driving voltages may include a first driving voltage VDD and a second driving voltage VSS supplied to the pixel array layer 340. The two or more power lines may include a first driving voltage line VDDL and a second driving voltage line VSSL. Two or more power lines may be electrically connected to patterns (e.g., metals) in the pixel array layer 340. Additionally, two or more power lines may include patterns (e.g., metals) in the pixel array layer 340.

Referring to FIG. 3, the encapsulation layer 250 may be located on the pixel array layer 340. The encapsulation layer 250 may prevent the organic layer disposed in the pixel array layer 340 from being exposed to moisture or oxygen.

As described above, in a conventional display device, the gate driving circuit is connected to or formed in a non-display area (i.e., bezel), However, in the display device 100 according to one or more example embodiments of the present disclosure, the gate driving circuit 130 may be disposed within the display area DA, thereby significantly reducing the size of the non-display area (i.e., bezel).

In addition, in a conventional display device, various power lines are arranged in the non-display area (i.e., bezel). However, in the display device 100 according to one or more example embodiments of the present disclosure, various power lines may be arranged in the display area DA, thereby further reducing the size of the non-display area (i.e., bezel).

In addition, the gate driving circuit 130 and/or various power lines may be arranged to overlap the pixel array layer 340 in the vertical direction even if they are arranged within the display area DA, so that a space where a plurality of subpixels SP are arranged may not be reduced. Accordingly, it is possible to reduce the size of the non-display area (i.e., bezel) without reducing the aperture ratio of the display area DA of the display panel 110.

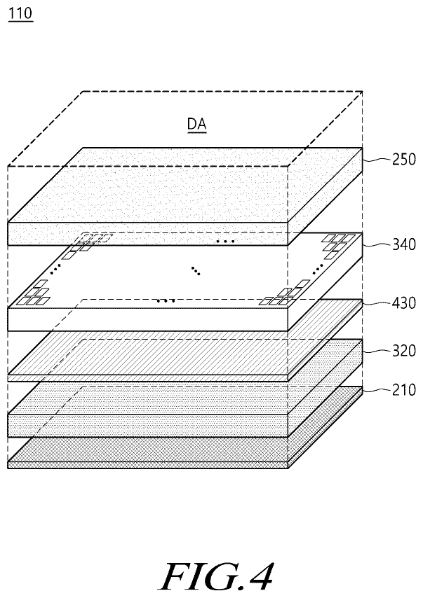

FIG. 4 illustrates another example of a stacked structure of a display panel 110 according to one or more example embodiments of the present disclosure.

Referring to FIG. 4, the display panel 110 according to one or more example embodiments of the present disclosure may further include a shielding layer 430 located between the base circuit layer 320 and the pixel array layer 340.

The shielding layer 430 may shield the electric field between the base circuit layer 320 and the pixel array layer 340. Accordingly, the base circuit layer 320 and the pixel array layer 340 may not have an unwanted electrical effect on each other.

Referring to FIG. 4, in order to increase the shielding performance of the shielding layer 430, the shielding layer 430 may be electrically connected to a power line located within the base circuit layer 320.

For example, the shielding layer 430 may be electrically connected to a first power line among two or more power lines PL1 to PLm located in the base circuit layer 320. Here, the first power line may be a power line to which the first driving voltage VDD supplied to the pixel array layer 340 is applied. Accordingly, the first power line may be electrically connected to the first driving voltage line VDDL disposed in the pixel array layer 340.

As another example, the shielding layer 430 may be electrically connected to a second power line among two or more power lines PL1 to PLm located in the base circuit layer 320. Here, the second power line may be a power line to which the second driving voltage VSS supplied to the pixel array layer 340 is applied. Accordingly, the second power line may be electrically connected to the second driving voltage line VSSL disposed in the pixel array layer 340.

Referring to FIG. 4, in order to increase the shielding performance of the shielding layer 430, the shielding layer 430 may be electrically connected to a metal located within the pixel array layer 340.

For example, the shielding layer 430 may be electrically connected to a first metal located within the pixel array layer 340. Here, the first metal may be a metal to which the first driving voltage VDD is applied. Here, the first metal is a metal to which the first driving voltage VDD is applied, and may be the first driving voltage line VDDL or a connection pattern connected to the first driving voltage line VDDL.

As another example, the shielding layer 430 may be electrically connected to a second metal located within the pixel array layer 340. Here, the second metal may be a metal to which the second driving voltage VSS is applied, and may be a second driving voltage line VSSL or a connection pattern connected to the second driving voltage line VSSL.

Referring to FIG. 4, the shielding layer 430 may electrically connect a metal located in the pixel array layer 340 and a metal located in the base circuit layer 320.

For example, the shielding layer 430 may electrically connect a first metal located within the pixel array layer 340 and a first power line located within the base circuit layer 320. Here, the first metal may be a metal to which the first driving voltage VDD is applied. Here, the first metal may be a metal to which the first driving voltage VDD is applied, and may be the first driving voltage line VDDL or a connection pattern connected to the first driving voltage line VDDL. The first power line may be a power line to which the first driving voltage VDD supplied to the pixel array layer 340 is applied.

In this example, the shielding layer 430 may be electrically connected to the light emitting device ED included in each of the plurality of subpixels SP and the source electrode or drain electrode of one of the plurality of pixel driving transistors. Referring to the equivalent circuit of the subpixel SP illustrated in FIG. 2, the shielding layer 430 may be electrically connected to a third node N3 of a first transistor T1 among the plurality of pixel driving transistors included in each of the plurality of subpixels SP. The third node N3 of the first transistor T1 may be a drain electrode or a source electrode.

As another example, the shielding layer 430 may electrically connect a second metal located within the pixel array layer 340 and a second power line located within the base circuit layer 320. Here, the second metal may be a metal to which the second driving voltage VSS is applied, and may be a second driving voltage line VSSL or a connection pattern connected to the second driving voltage line VSSL. The second power line may be a power line to which the second driving voltage VSS supplied to the pixel array layer 340 is applied.

In this example, the shielding layer 430 may be electrically connected to a common electrode CE of the light emitting device ED included in each of the plurality of subpixels SP.

Referring to FIG. 4, the display panel 110 according to one or more example embodiments of the present disclosure may include a substrate 210, a pixel array layer 340 located on the substrate 210 and in which a plurality of subpixels SP are arranged in the display area DA displaying an image, a base circuit layer 320 located between the substrate 210 and the pixel array layer 340, and a shielding layer 430 located between the base circuit layer 320 and the pixel array layer 340.

The base circuit layer 320 may include an organic layer disposed on a gate driving transistor included in the gate driving circuit 130.

The base circuit layer 320 may include two or more power lines to which two or more common pixel driving voltages supplied to the pixel array layer 340 are applied.

The shielding layer 430 may electrically connect a metal disposed in the pixel array layer 340 and a metal (e.g., power line) disposed in the base circuit layer 320.

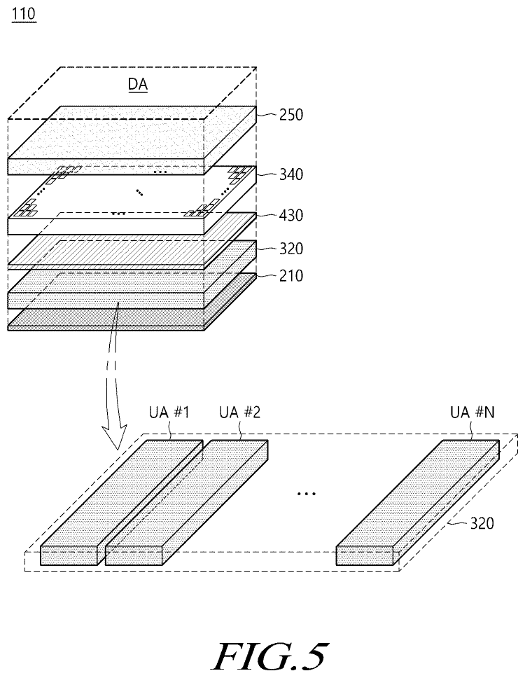

FIG. 5 illustrates a plurality of unit areas UA #1 to UA #N (N is a natural number of 2 or more) constituting a base circuit layer 320 within a display area DA of a display panel 10 according to one or more example embodiments of the present disclosure.

Referring to FIG. 5, the base circuit layer 320 may be disposed in the display area DA, and may be located below the pixel array layer 340.

The base circuit layer 320 may include a plurality of unit areas UA #1 to UA #N (where N is a natural number of 2 or more).

The base circuit layer 320 may include a plurality of unit areas UA #1 to UA #N (N is a natural number of 2 or more) arranged over the entire display area DA.

Each of the plurality of unit areas UA #1 to UA #N may have the same structure.

Hereinafter, it will be described a structure of a first unit area UA #1 among the plurality of unit areas UA #1 to UA #N. Among the plurality of unit areas UA #1 to UA #N), the remaining unit areas UA #2 to UA #N except for the first unit area UA #1 may have the same structure as the first unit area UA #1.

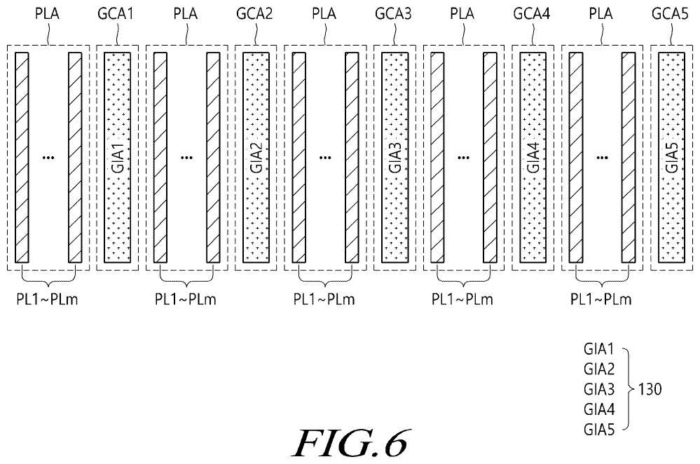

FIG. 6 illustrates a structure of a first unit area UA #1 among a plurality of unit areas UA #1 to UA #N constituting (or included in) a base circuit layer 320 in the display area DA of a display panel 110 according to one or more example embodiments of the present disclosure.

Referring to FIG. 6, each of the plurality of unit areas UA #1 to UA #N may include a plurality of subcircuit areas GCA1 to GCA5, and a plurality of power line areas PLA. The number of subcircuit areas GCA1 to GCA5 included in each of the unit areas UA #1 to UA #N may vary depending on the type (or number) of gate signals supplied to the subpixel SP.

Referring to FIG. 6, a plurality of subcircuit areas GCA1 to GCA5 and a plurality of power line areas PLA may be arranged alternately.

Referring to FIG. 6, the plurality of power line areas PLA may include a plurality of power lines PL1 to PLm (where m is a natural number of 2 or more) to which a voltage with a constant voltage level is applied. In an example, two or more power lines of the plurality of power lines PL1 to PLm may be supplied with a same voltage (e.g., one of VDD, VSS, VREF, or VAR). In another example, two or more power lines of the plurality of power lines PL1 to PLm may be supplied with different voltages (e.g., two or more of VDD, VSS, VREF, and VAR).

Referring to FIG. 6, the plurality of subcircuit areas GCA1 to GCA5 may include a plurality of subcircuits GIA1 to GIA5 included in the gate driving circuit 130. A plurality of subcircuits GIA1 to GIA5 may be configured to output different types of gate signals.

Referring to FIG. 6, since a plurality of power lines PL1 to PLm are arranged identically in each of the plurality of power line areas PLA, the width of each of the plurality of power line areas PLA may be the same.

At least one of the plurality of power lines PL1 to PLm included in each of the plurality of power line areas PLA may have a width different from the others.

Referring to FIG. 6, as the plurality of subcircuits GIA1 to GIA5 are configured to output different types of gate signals, at least one of the plurality of subcircuit areas GCA1 to GCA5 may have a width different from the remaining subcircuit areas.

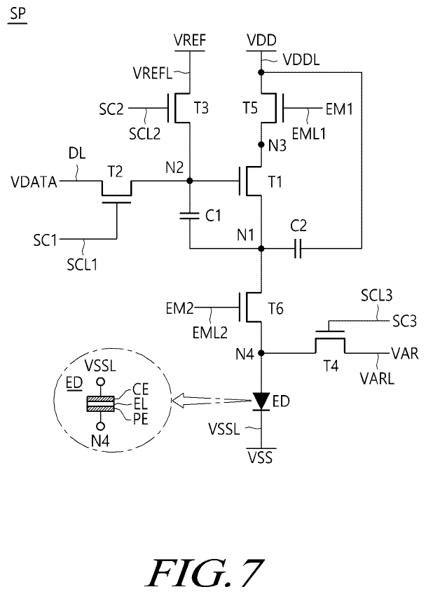

Meanwhile, each of the plurality of subpixels SP disposed on the display panel 110 according to one or more example embodiments of the present disclosure may be configured as simply as the equivalent circuit of FIG. 2, but may be configured more complexly than the equivalent circuit in FIG. 2. Hereinafter, it will be described as an example an equivalent circuit of the subpixel SP which is more complex than the equivalent circuit of FIG. 2 with reference to FIG. 7.

FIG. 7 illustrates an equivalent circuit of a subpixel SP in a display panel 110 according to one or more example embodiments of the present disclosure.

Referring to FIG. 7, each of the plurality of subpixels SP disposed on the display panel 110 according to one or more example embodiments of the present disclosure may include a light emitting device ED, six pixel driving transistors T1 to T6, and two capacitors Cst and Ca. The six pixel driving transistors T1 to T6 may include a first transistor T1, a second transistor T2, a third transistor T3, a fourth transistor T4, a fifth transistor T5 and a sixth transistor T6. The two capacitors Cst and Ca may include a first capacitor C1 and a second capacitor C2.

The light emitting device ED may include a pixel electrode PE, a device intermediate layer EL and a common electrode CE. The pixel electrode PE may correspond to a fourth node N4. The common electrode CE may be connected to a second driving voltage line VSSL. The common electrode CE may receive a second driving voltage VSS through the second driving voltage line VSSL.

The first transistor T1 may correspond to a driving transistor. The first transistor T1 may include a first node N1, a second node N2, and a third node N3. In the first transistor T1, the first node N1 may be a source electrode or a drain electrode, the second node N2 may be a gate electrode, and the third node N3 may be a drain electrode or a source electrode.

The second transistor T2 may be controlled to be turned on or off by a first scan signal SC1 supplied from a first scan line SCL1, and may control the connection between the second node N2 of the first transistor T1 and the data line DL.

The second transistor T2 may be turned on by the first scan signal SC1 having a turn-on level voltage, and may transmit the data signal VDATA supplied from the data line DL to the second node N2 of the first transistor T1.

The third transistor T3 may be controlled to be turned on or off by a second scan signal SC2 supplied from a second scan line SCL2, and may control the connection between the second node N2 of the first transistor T1 and a reference voltage line VREFL.

The third transistor T3 may be turned on by the second scan signal SC2 having a turn-on level voltage, and may transfer a reference voltage VREF supplied from the reference voltage line VREFL to the second node N2 of the first transistor T1.

The fourth transistor T4 may be controlled to be turned on or off by a third scan signal SC3 supplied from ae third scan line SCL3, and may control the connection between a fourth node N4 corresponding to the pixel electrode PE of the light emitting device ED and a reset voltage line VARL.

The fourth transistor T4 may be turned on by the third scan signal SC3 having a turn-on level voltage, and may transfer a reset voltage VAR supplied from the reset voltage line VARL to the fourth node N4 corresponding to the pixel electrode PE of the light emitting device ED.

The fifth transistor T5 may be controlled to be turned on or off by a first emission control signal EM1 supplied from a first emission control line EML1, and may control the connection between the third node N3 of the first transistor T1 and the first driving voltage line VDDL.

The fifth transistor T5 may be turned on by the first emission control signal EM1 having a turn-on level voltage, and may transfer a first driving voltage VDD supplied from the first driving voltage line VDDL to the third node N3 of the first transistor T1.

The sixth transistor T6 may be controlled to be turned on or off by a second emission control signal EM2 supplied from a second emission control line EML2, and may control the connection between the first node N1 of the first transistor T1 and the fourth node N4 corresponding to the pixel electrode PE of the light emitting device ED.

The sixth transistor T6 may be turned on by the second emission control signal EM2 having a turn-on level voltage, and may electrically connect the first node N1 of the first transistor T1 and the fourth node N4 corresponding to the pixel electrode PE of the light emitting device ED. The first capacitor C1 may correspond to a storage capacitor Cst.

The first capacitor C1 may be connected between the second node N2 of the first transistor T1 and the first node N1 of the first transistor T1. The first capacitor C1 may include a capacitor electrode corresponding to the second node N2 of the first transistor T1 and a capacitor electrode corresponding to the first node N1 of the first transistor T1.

The second capacitor C2 may be connected between the first node N1 of the first transistor T1 and the first driving voltage line VDDL. The second capacitor C2 may include a capacitor electrode corresponding to the first node N1 of the first transistor T1 and a capacitor electrode corresponding to the first driving voltage line VDDL.

In order to drive one subpixel SP, there may be supplied a data signal VDATA corresponding to an image signal and five types of gate signals to one subpixel SP. Here, the five gate signals may include a first scan signal SC1, a second scan signal SC2, a third scan signal SC3, a first emission control signal EM1, and a second emission control signal EM2.

In addition, in order to drive one subpixel SP, four pixel driving voltages may be supplied to one subpixel SP. Here, the four pixel driving voltages may include a first driving voltage VDD, a second driving voltage VSS, a reference voltage VREF, and a reset voltage VAR.

In order to drive one subpixel SP, one subpixel SP may be connected to a data line DL, five gate lines GL, and four pixel driving voltage lines. Here, the five gate lines GL may include a first scan line SCL1, a second scan line SCL2, a third scan line SCL3, a first emission control line EML1, and a second emission control line EML2. The four pixel driving voltage lines may include a first driving voltage line VDDL, a second driving voltage line VSSL, a reference voltage line VREFL, and a reset voltage line VARL.

Hereinafter, a structure of each of the plurality of unit areas UA #1 to UA #N included in the base circuit layer 320 will be described based on the first unit area UA #1, in the case that the equivalent circuit of the subpixel SP is as shown in FIG. 7.

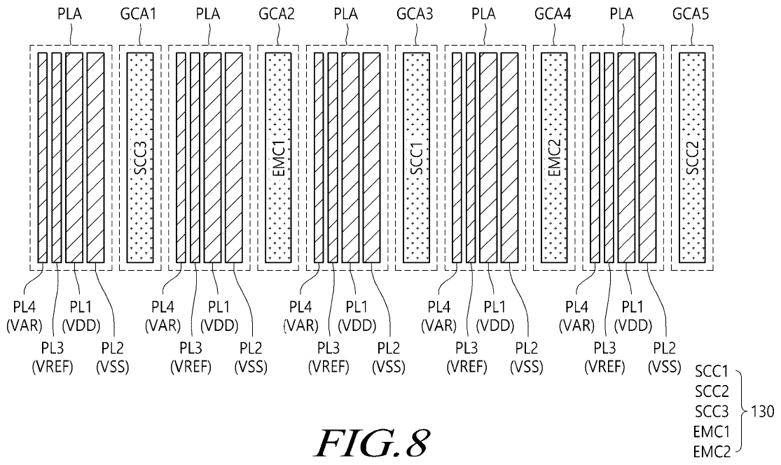

FIG. 8 illustrates an example of a structure of a first unit area UA #1 among a plurality of unit areas UA #1 to UA #N in the base circuit layer 320 within the display area DA of the display panel 110 according to one or more example embodiments of the present disclosure. Here, among the plurality of unit areas UA #1 to UA #N), the remaining unit areas UA #2 to UA #N except for the first unit area UA #1 may have the same structure as the first unit area UA #1.

FIG. 8 illustrates a structure of the first unit area UA #1 when the subpixel SP has the same structure as that of FIG. 7. Accordingly, since the types (or number) of gate signals supplied to the subpixels SP of FIG. 7 are five, the number of subcircuit areas GCA1 to GCA5 included in each of the unit areas UA #1 to UA #N may be five.

Referring to FIG. 8, each of the plurality of unit areas UA #1 to UA #N may include five subcircuit areas GCA1 to GCA5 and a plurality of power line areas PLA.

Referring to FIG. 8, five subcircuit areas GCA1 to GCA5 and five power line areas PLA may be arranged alternately.

First to fourth power lines PL1 to PL4 may be disposed in each of the five power line areas PLA. A voltage having a constant voltage level may be applied to the first to fourth power lines PL1 to PL4.

For example, the first power line PL1 may be a power line to which the first driving voltage VDD is applied, and the second power line PL2 may be a power line to which the second driving voltage VSS is applied. The third power line PL3 may be a power line to which a reference voltage VREF is applied, and the fourth power line PLA may be a power line to which a reset voltage VAR is applied.

The first power line PL1 and the second power line PL2 may have the same or substantially the same width. The third power line PL3 and the fourth power line PLA may have the same or substantially the same width.

The first power line PL1 and the second power line PL2 may have a wider width than the third power line PL3 and the fourth power line PL4.

Referring to FIG. 8, the five subcircuit areas GCA1 to GCA5 may include a first subcircuit GIA1, a second subcircuit GIA2, a third subcircuit GIA3, a fourth subcircuit GIA4, and a fifth subcircuit GIA5 included in the gate driving circuit 130, respectively. Five subcircuits GIA1 to GIA5 may be configured to output different types of gate signals.

For example, the first subcircuit GIA1 disposed in the first subcircuit area GCA1 may be a third scan circuit SCC3 which generates and outputs the third scan signal SC3. The second subcircuit GIA2 disposed in the second subcircuit area GCA2 may be a first emission control circuit EMC1 which generates and outputs the first emission control signal EM1. The third subcircuit GIA3 disposed in the third subcircuit area GCA3 may be a first scan circuit SCC1 which generates and outputs the first scan signal SC1. The fourth subcircuit GIA4 disposed in the fourth subcircuit area GCA4 may be a second emission control circuit EMC2 which generates and outputs the second emission control signal EM2. The fifth subcircuit GIA5 disposed in the fifth subcircuit area GCA5 may be a second scan circuit SCC2 which generates and outputs the second scan signal SC2.

First to third scan signals SC1, SC2 and SC3 output from the first to third scan circuits SCC1, SCC2 and SCC3, and the first and second emission control signals EM1 and EM2 output from the first and second emission control circuits EMC1 and EMC2 may be supplied from the base circuit layer 320 to the subpixels SP disposed in the pixel array layer 340.

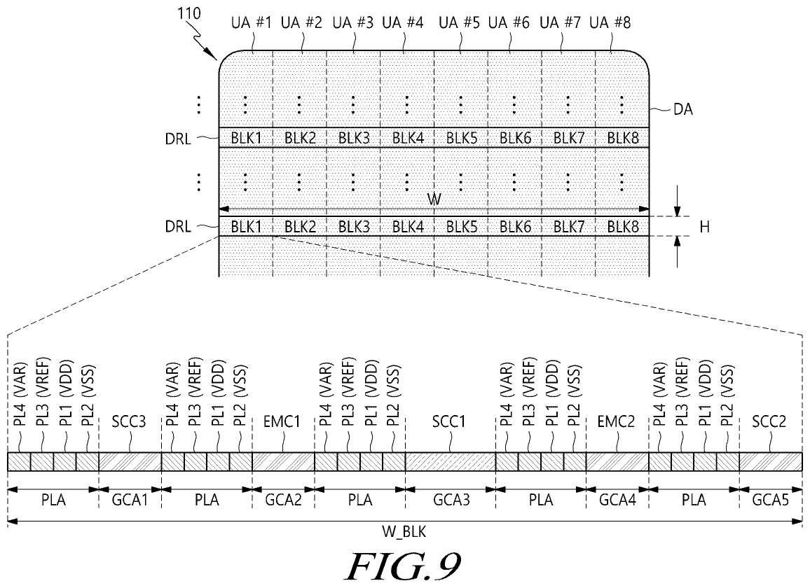

FIG. 9 illustrates an example of a structure of one driving line area in the base circuit layer 320 in the display area DA of the display panel 110 according to one or more example embodiments of the present disclosure.

Referring to FIG. 9, for example, the display area DA of the display panel 110 may include first to eighth unit areas UA #1 to UA #8. Here, the first to eighth unit areas UA #1 to UA #8 may be areas formed in the base circuit layer 320.

The display area DA of the display panel 110 may include a plurality of driving line areas DRL. Each of the plurality of driving line areas DRL may correspond to one subpixel row (or one subpixel column).

Each of the plurality of driving line areas DRL may include first to eighth blocks BLK1 to BLK8 corresponding to first to eighth unit areas UA #1 to UA #8.

The first to eighth blocks BLK1 to BLK8 may be a portion of each of the first to eighth unit areas UA #1 to UA #8. That is, the first block BLK1 may be a part of the first unit area UA #1, the second block BLK2 may be a part of the second unit area UA #2, the third block BLK3 may be a part of the third unit area UA #3, the fourth block BLK4 may be a part of the fourth unit area UA #4, the fifth block BLK5 may be a part of the fifth unit area UA #5, the sixth block BLK6 may be a part of the sixth unit area UA #6, and the seventh block BLK7 may be a part of the seventh unit area UA #7, and the eighth block BLK8 may be a part of the eighth unit area UA #8.

Accordingly, the first to eighth blocks BLK1 to BLK8 may have the same structure.

Referring to FIG. 9, the sum of the widths W_BLK of the first to eighth blocks BLK1 to BLK8 may be equal to the row direction length W of one driving line area DRL. The column length H of one driving line area DRL may correspond to the column direction length of one subpixel (or one subpixel row).

Taking the first block BLK1 among the first to eighth blocks BLK1 to BLK8 as an example, the first block BLK1 may include five subcircuit areas GCA1 to GCA5 and a plurality of power line areas PLA. Five subcircuit areas GCA1 to GCA5 and five power line areas PLA may be arranged alternately.

First to fourth power lines PL1 to PL4 may be disposed in each of the five power line areas PLA. A voltage having a constant voltage level may be applied to the first to fourth power lines PL1 to PL4.

For example, the first power line PL1 may be a power line to which the first driving voltage VDD is applied, and the second power line PL2 may be a power line to which the second driving voltage VSS is applied. The third power line PL3 may be a power line to which a reference voltage VREF is applied, and the fourth power line PLA may be a power line to which a reset voltage VAR is applied.

The five subcircuit areas GCA1 to GCA5 may include a first subcircuit GIA1, a second subcircuit GIA2, a third subcircuit GIA3, a fourth subcircuit GIA4, and a fifth subcircuit GIA5 included in the gate driving circuit 130, respectively. Five subcircuits GIA1 to GIA5 may be configured to output different types of gate signals.

For example, the first subcircuit GIA1 disposed in the first subcircuit area GCA1 may be a third scan circuit SCC3 which generates and outputs the third scan signal SC3. The second subcircuit GIA2 disposed in the second subcircuit area GCA2 may be a first emission control circuit EMC1 which generates and outputs the first emission control signal EM1. The third subcircuit GIA3 disposed in the third subcircuit area GCA3 may be a first scan circuit SCC1 which generates and outputs the first scan signal SC1. The fourth subcircuit GIA4 disposed in the fourth subcircuit area GCA4 may be a second emission control circuit EMC2 which generates and outputs the second emission control signal EM2. The fifth subcircuit GIA5 disposed in the fifth subcircuit area GCA5 may be a second scan circuit SCC2 which generates and outputs the second scan signal SC2.

The first to third scan signals SC1, SC2 and SC3 output from the first to third scan circuits SCC1, SCC2 and SCC3, and the first and second emission control signals EM1 and EM2 output from the first and second emission control circuits EMC1 and EMC2 may be supplied from the base circuit layer 320 to the subpixels SP disposed in the pixel array layer 340.

For example, the first scan circuit SCC1 may have a width wider than each of the second scan circuit SCC2, the third scan circuit SCC3, the first emission control circuit EMC1 and the second emission control circuit EMC2.

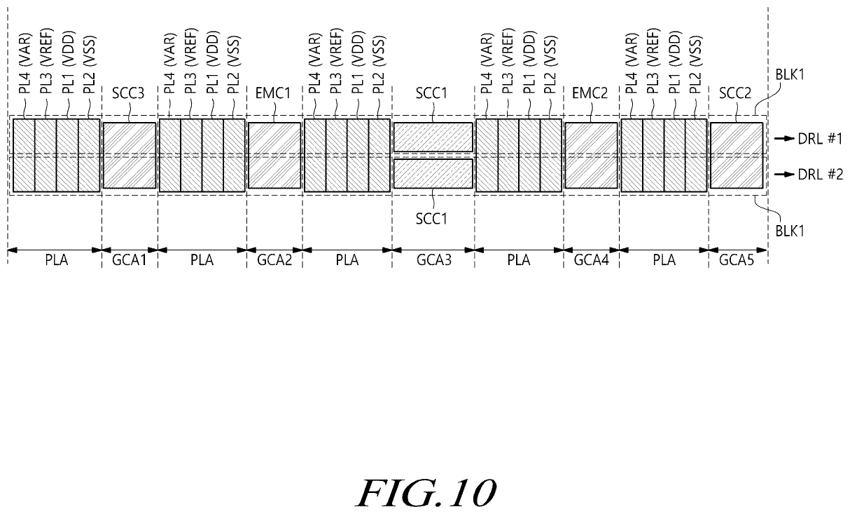

FIG. 10 illustrates an example of first blocks BLK1 in two driving line areas DRL #1 and DRL #2 in the base circuit layer 320 within the display area DA of the display panel 110 according to one or more example embodiments of the present disclosure.

Referring to FIG. 10, one third scan circuit SCC3 disposed in the first subcircuit area GCA1 may be arranged across two first blocks BLK1 included in two driving line areas DRL #1 and DRL #2. One first emission control circuit EMIC disposed in the second subcircuit area GCA2 may be arranged across two first blocks BLK1 included in two driving line areas DRL #1 and DRL #2. One second emission control circuit EMC2 disposed in the fourth subcircuit area GCA4 may be arranged across two first blocks BLK1 included in two driving line areas DRL #1 and DRL #2. One second scan circuit SCC2 disposed in the fifth subcircuit area GCA5 may be arranged across two first blocks BLK1 included in two driving line areas DRL #1 and DRL #2.

Referring to FIG. 10, one first scan circuit SCC1 disposed in the third subcircuit area GCA3 may be arranged in one first block BLK1 included in the first driving line area DRL #1. Another first scan circuit SCC1 disposed in the third subcircuit area GCA3 may be disposed in one first block BLK1 included in the second driving line area DRL #2.

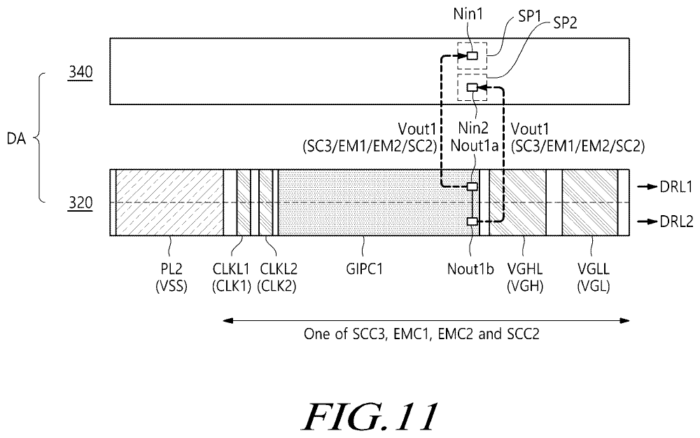

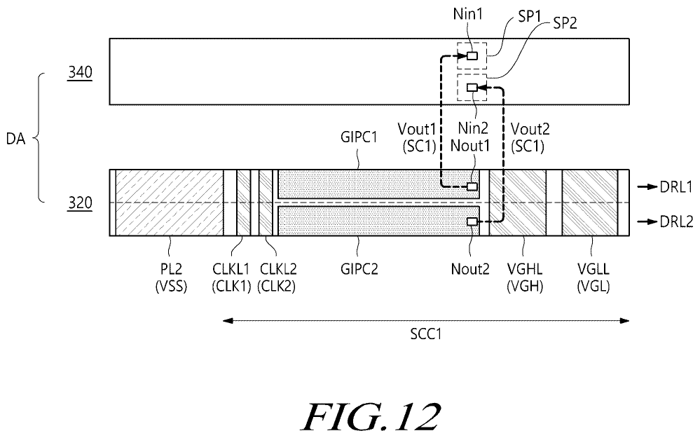

It will be described the detailed structures of each of the third scan circuit SCC3, the first emission control circuit EMC1, the second emission control circuit EMC2 and second scan circuit SCC2 according to the example of FIG. 10 with reference to FIG. 11. Next, it will be described the detailed structure of the first scan circuit SCC1 according to the example of FIG. 10 with reference to FIG. 12.

FIG. 11 is a diagram illustrating a vertical correspondence structure between a base circuit layer 320 and a pixel array layer 340 in a display area DA of a display panel 110 according to one or more example embodiments of the present disclosure.

Referring to FIG. 11, each of the third scan circuit SCC3, the first emission control circuit EMC1, the second emission control circuit EMC2, and the second scan circuit SCC2 may be disposed in the base circuit layer 320.

Referring to FIG. 11, one third scan circuit SCC3 may be disposed in two driving line areas DRL1 and DRL2 within one unit area. One first emission control circuit EMC1 may be disposed in two driving line areas DRL1 and DRL2 within one unit area. One second emission control circuit EMC2 may be disposed in two driving line areas DRL1 and DRL2 within one unit area. One second scan circuit SCC2 may be disposed in two driving line areas DRL1 and DRL2 within one unit area.

Referring to FIG. 11, the area where any one of the third scan circuit SCC3, the first emission control circuit EMC1, the second emission control circuit EMC2 and the second scan circuit SCC2 is formed may include a clock line area where clock lines CLKL1 and CLKL2 are arranged, and a gate voltage line area where a first gate voltage line VGHL transmitting a first gate voltage VGH and a second gate voltage line VGLL transmitting a second gate voltage VGL are arranged.

Referring to FIG. 11, the area where any one of the third scan circuit SCC3, the first emission control circuit EMC1, the second emission control circuit EMC2 and the second scan circuit SCC2 is formed may further include a gate-in-panel circuit area where a first gate-in-panel circuit GIPC1 is disposed. Here, the first gate-in-panel circuit GIPC1 may be included in a gate driving circuit 130 of the GIP type.

Referring to FIG. 11, the gate-in-panel circuit area may be disposed between the clock line area and the gate voltage line area.

In the clock line area, there may be disposed a first clock line CLKL1 transmitting a first clock signal CLK1 and a second clock line CLKL2 transmitting a second clock signal CLK2.

The first gate voltage VGH may be a voltage at a higher level than the second gate voltage VGL. For example, the first gate voltage VGH may correspond to the turn-on level voltage of the first gate signal Vout1, and the second gate voltage VGL may correspond to the turn-off level voltage of the first gate signal Vout1. As another example, the first gate voltage VGH may correspond to the turn-off level voltage of the first gate signal Vout1, and the second gate voltage VGL may correspond to the turn-on level voltage of the first gate signal Vout1.

The first gate-in-panel circuit GIPC1 may correspond to any one of a substantial third scan circuit SCC3, a substantial first emission control circuit EMC1, a substantial second emission control circuit EMC2, and a substantial second scan circuit SCC2.

The first gate-in-panel circuit GIPC1 may be arranged across two driving line area DRL1 and DRL2. The first gate-in-panel circuit GIPC1 may generate and output two first gate signals Vout1 through two first output nodes Nout1a and Nout1b corresponding to the two driving line areas DRL1 and DRL2.

The two first gate signals Vout1 may be one of the third scan signal SC3, the first emission control signal EM1, the second emission control signal EM2, and the second scan signal SC2.

The two first gate signals Vout1 may be applied to the two input nodes Nin1 and Nin2 disposed in the pixel array layer 340, respectively. The two input nodes Nin1 and Nin2 may be nodes existing in two subpixels SP1 and SP2 arranged in different subpixel rows.

The two first gate signals Vout1 output from the two first output nodes Nout1a and Nout1b in the base circuit layer 320 may be input to two input nodes Nin1 and Nin2 within the pixel array layer 340.

Referring to FIG. 11, the base circuit layer 320 and the pixel array layer 340 may overlap each other in the vertical direction within the display area DA.

Referring to FIG. 11, there may exist two connection patterns electrically connecting the two first output nodes Nout1a and Nout1b in the base circuit layer 320 and the two input nodes Nin1 and Nin2 in the pixel array layer 340 between the base circuit layer 320 and the pixel array layer 340.

Referring to FIG. 11, the two first gate signals Vout1 output from the two first output nodes Nout1a and Nout1b in the base circuit layer 320 may be input to two input nodes Nin1 and Nin2 in the pixel array layer 340 through two connection patterns existing between the base circuit layer 320 and the pixel array layer 340.

FIG. 12 is another diagram illustrating a vertical correspondence structure between a base circuit layer 320 and a pixel array layer 340 in a display area DA of a display panel 110 according to one or more example embodiments of the present disclosure.

Referring to FIG. 12, a first scan circuit SCC1 may be disposed on the base circuit layer 320.

Referring to FIG. 12, one first scan circuit SCC1 may be disposed in each of the two driving line areas DRL1 and DRL2 within a single unit area.

Referring to FIG. 12, the area where the first scan circuit SCC1 is formed may include a clock line area in which the clock lines CLKL1 and CLKL2 are arranged, and a gate voltage line area in which a first gate voltage line VGHL transmitting a first gate voltage VGH and a second gate voltage line VGLL transmitting a second gate voltage VGL are disposed.

Referring to FIG. 12, the area where the first scan circuit SCC1 is formed may further include a gate-in-panel circuit area in which a first gate-in-panel circuit GIPC1 and the second gate-in-panel circuit GIPC2 are disposed. Here, the second gate-in-panel circuit GIPC2 may be included in a gate driving circuit 130 of a GIP type.

Referring to FIG. 12, the gate-in-panel circuit area may be disposed between the clock line area and the gate voltage line area.

In the clock line area, there may be disposed a first clock line CLKL1 for transmitting a first clock signal CLK1 and a second clock line CLKL2 for transmitting a second clock signal CLK2.

The first gate voltage VGH may be a voltage at a higher level than the second gate voltage VGL. For example, the first gate voltage VGH may correspond to the turn-on level voltage of the gate signals Vout1 and Vout2, and the second gate voltage VGL may correspond to the turn-off level voltage of the gate signals Vout1 and Vout2. As another example, the first gate voltage VGH may correspond to the turn-off level voltage of the gate signals Vout1 and Vout2, and the second gate voltage VGL may correspond to the turn-on level of the gate signals Vout1 and Vout2.

Each of the first gate-in-panel circuit GIPC1 and the second gate-in-panel circuit GIPC2 may correspond to a substantial first scan circuit SCC1.

The first gate-in-panel circuit GIPC1 may be disposed in the first driving line area DRL1, and the second gate-in-panel circuit GIPC2 may be disposed in the second driving line area DRL2.

The first gate-in-panel circuit GIPC1 may generate and output the first gate signal Vout1 through a first output node Nout1 corresponding to the first driving line area DRL1. The second gate-in-panel circuit GIPC2 may generate and output the second gate signal Vout2 through a second output node Nout2 corresponding to the second driving line area DRL2.

The first gate signal Vout1 and the second gate signal Vout2 may be first scan signals SC1. The first gate signal Vout1 and the second gate signal Vout2 may be applied to two input nodes Nin1 and Nin2 disposed in the pixel array layer 340, respectively. The two input nodes Nin1 and Nin2 may be nodes existing in two subpixels SP1 and SP2 arranged in different subpixel rows.

The first gate signal Vout1 output from the first output node Nout1 in the base circuit layer 320 may be input to the first input node Nin1 in the pixel array layer 340, and the second gate signal Vout2 output from the second output node Nout2 in the base circuit layer 320 may be input to the second input node Nin2 in the pixel array layer 340.

Referring to FIG. 12, the base circuit layer 320 and the pixel array layer 340 may overlap with each other in the vertical direction within the display area DA.

Referring to FIG. 12, a first connection pattern electrically connecting the first output node Nout1 in the base circuit layer 320 and the first input node Nin1 in the pixel array layer 340 may be disposed between the base circuit layer 320 and pixel array layer 340. A second connection pattern electrically connecting the second output node Nout2 in the base circuit layer 320 and the second input node Nin2 in the pixel array layer 340 may exist between the base circuit layer 320 and the pixel array layer 340.

Referring to FIG. 12, the first gate signal Vout1 output from the first output node Nout1 in the base circuit layer 320 may be input to the first input node Nin1 in the pixel array layer 340 through the first connection pattern existing between the base circuit layer 320 and the pixel array layer 340. The second gate signal Vout2 output from the second output node Nout2 in the base circuit layer 320 may be input to the second input node Nin2 in the pixel array layer 340 through a second connection pattern existing between the base circuit layer 320 and the pixel array layer 340.

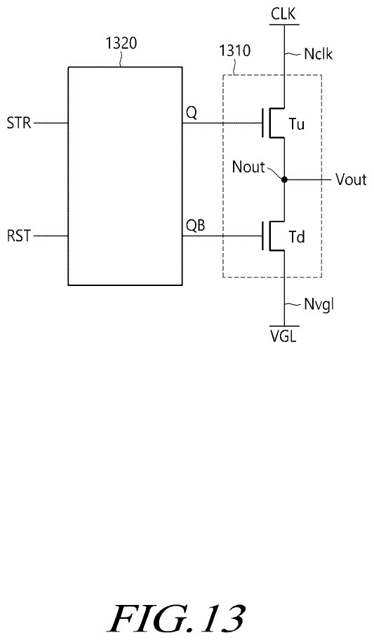

FIG. 13 is a diagram briefly illustrating a gate driving circuit 130 according to one or more example embodiments of the present disclosure.

As described above, the gate driving circuit 130 according to one or more example embodiments of the present disclosure may include a plurality of subcircuits GIA1 to GIA5. For example, the plurality of subcircuits GIA1 to GIA5 may be first to third scan circuits SCC1, SCC2 and SCC3, and first and second emission control circuits EMC1 and EMC2.

Referring to FIG. 13, each of the plurality of subcircuits GIA1 to GIA5 may include an output buffer 1310 and a control circuit 1320.

The output buffer 1310 may include a pull-up transistor Tu connected between a clock node Nelk to which a clock signal CLK is input and an output node Nout from which the gate signal Vout is output, and a pull-down transistor Td connected between an output node Nout from which the gate signal Vout is output and a low voltage node Nvgl to which the second gate voltage VGL is input.

The gate signal Vout may be one of a first scan signal SC1, a second scan signal SC2, a third scan signal SC3, a first emission control signal EM1, and a second emission control signal EM2.

The output node Nout may be electrically connected to one of a first scan line SCL1, a second scan line SCL2, a third scan line SCL3, a first emission control line EML1, and a second emission control line EML2.

The gate node of the pull-up transistor Tu may correspond to a Q node. The pull-up transistor Tu may be turned on or turned off depending on the voltage level of the Q node.

The gate node of the pull-down transistor Td may correspond to a QB node. The pull-down transistor Td may be turned on or turned off depending on the voltage level of the QB node.

The voltage level of the Q node and the voltage level of the QB node may be opposite to each other. That is, when the voltage level of the Q node is a high level, the voltage level of the QB node may be a low level. When the voltage level of the Q node is a low level, the voltage level of the QB node may be a high level.

Since the voltage level of the Q node and the voltage level of the QB node are opposite to each other, the on-off state of the pull-up transistor Tu and the on-off state of the pull-down transistor Td may be different from each other. That is, when the pull-up transistor Tu is turned on, the pull-down transistor Td may be turned off. When the pull-up transistor Tu is turned off, the pull-down transistor Td may be turned on.

The control circuit 1320 may receive control signals such as a start signal STR and a reset signal RST, and control the voltage level of the Q node and the voltage level of the QB node. The control circuit 1320 may include a plurality of transistors.

When the voltage level of the Q node becomes a high level and the voltage level of the QB node becomes a low level by the control circuit 1320, the pull-up transistor Tu may be turned on, and a gate signal Vout having a high level voltage of the clock signal CLK may be output to the output node Nout.

When the voltage level of the Q node becomes a low level and the voltage level of the QB node becomes a high level by the control circuit 1320, the pull-down transistor Td may be turned on, and a gate signal Vout having a second gate voltage VGL corresponding to a low level voltage may be output to the output node Nout.

The transistors Tu and Td included in the output buffer 1310 and a plurality of transistors included in the control circuit 1320 may be referred to as gate driving transistors.

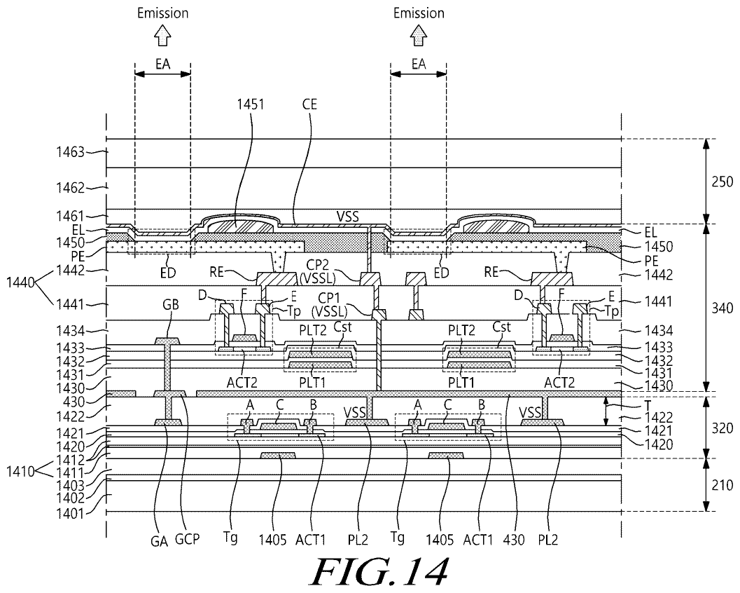

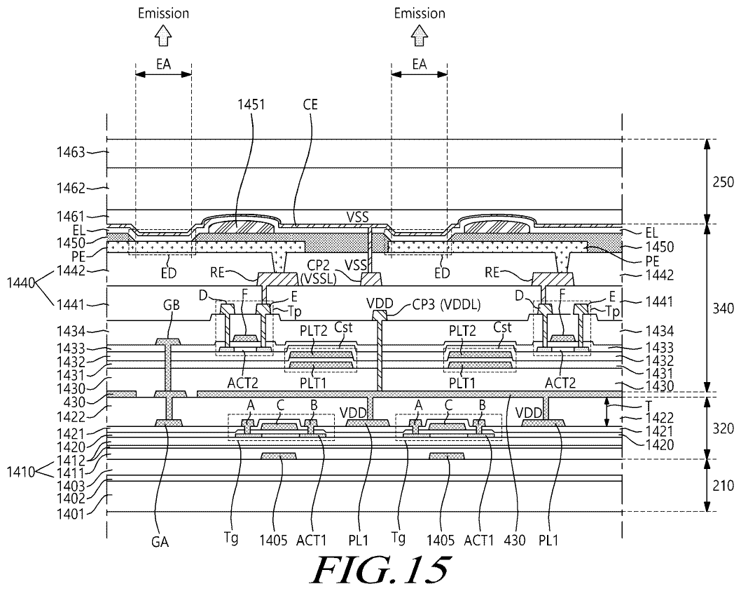

Hereinafter, a vertical structure of the display panel 110 according to the one or more example embodiments of the present disclosure described above will be described in more detail with reference to FIGS. 14 and 15.

FIG. 14 is a cross-sectional view of a display area DA of a display panel 110 according to one or more example embodiments of the present disclosure.

Referring to FIG. 14, the display area DA of the display panel 110 may include a substrate 210, a base circuit layer 320, a shielding layer 430, a pixel array layer 340, and an encapsulation layer 250.

The substrate 210 may include a first substrate 1401, an intermediate layer 1402, and a second substrate 1403. The intermediate layer 1402 may be disposed between the first substrate 1401 and the second substrate 1403. For example, at least one of the first substrate 1401 and the second substrate 1403 may be a substrate containing polyimide (PI).

The base circuit layer 320 may be located on the substrate 210.

The base circuit layer 320 may include a lower shield metal 1405, a plurality of gate driving transistors Tg constituting (or included in) the gate driving circuit 130, and various insulating films 1410, 1420 and 1421 for forming the plurality of gate driving transistors Tg.

Each of the plurality of gate driving transistors Tg may include a first active layer ACT1, a first source electrode A, a first drain electrode B, and a first gate electrode C.

The various insulating films 1410, 1420 and 1421 may include a first buffer layer 1410, a first gate insulating film 1420, and a first interlayer insulating film 1421.

The lower shield metal 1405 may be disposed on the substrate 210.

The first buffer layer 1410 may be disposed on the lower shield metal 1405.

The first buffer layer 1410 may include a multi-buffer layer 1411 and an active buffer layer 1412. The multi-buffer layer 1411 may be disposed on the lower shield metal 1405, and the active buffer layer 1412 may be disposed on the multi-buffer layer 1411.

The first active layer ACT1 may be disposed on the active buffer layer 1412.

The first gate insulating film 1420 may be disposed on the first active layer ACT1.

The first gate electrode C may be disposed on the first gate insulating film 1420, and may overlap with a portion of the first active layer ACT1. A portion of the first active layer ACT1 overlapping with the first gate electrode C may be a channel area.

The first interlayer insulating film 1421 may be disposed on the first gate electrode C.

The first source electrode A and the first drain electrode B may be disposed on the first interlayer insulating film 1421. The first source electrode A may be directly or indirectly connected to a first portion of the first active layer ACT1 through a first hole of the first interlayer insulating film 1421. The first drain electrode B may be directly or indirectly connected to a second portion of the first active layer ACT1 through a second hole of the first interlayer insulating film 1421. The area between the first and second portions of the first active layer ACT1 may be a channel area.

The transistor included in the gate driving circuit 130 may be referred to as a gate driving transistor Tg. The transistors included in the gate driving circuit 130 may include a pull-up transistor Tu and a pull-down transistor Td included in the output buffer 1310, and a plurality of transistors included in the control circuit 1320.

In the base circuit layer 320, there may be disposed a plurality of power lines PL1 to PLm to which a plurality of pixel driving voltages supplied to the pixel array layer 340 are applied in addition to the gate driving circuit 130. The plurality of power lines PL1 to PLm may include a second power line PL2 to which the second driving voltage VSS supplied to the pixel array layer 340 is applied.

The base circuit layer 320 may include an organic layer 1422 disposed on a plurality of gate driving transistors Tg included in the gate driving circuit 130.

The organic layer 1422 may be disposed on a plurality of gate driving transistors Tg and a plurality of power lines PL1 to PLm included in the gate driving circuit 130 to reduce a step in the base circuit layer 320.

In addition, the organic layer 1422 may reduce unnecessary parasitic capacitance between a metal disposed on the base circuit layer 320 and a metal disposed within the base circuit layer 320.

An upper surface of the organic layer 1422 may have a smaller step than a back surface of the organic layer 1422.

The organic layer 1422 may have a thickness T greater than a thickness of the first gate insulating film 1420 between the first gate electrode C of each of the plurality of gate driving transistors Tg and the first active layer ACT1.

The shielding layer 430 may be disposed on the base circuit layer 320, and the pixel array layer 340 may be disposed on the shielding layer 430. That is, the shielding layer 430 may be located between the base circuit layer 320 and the pixel array layer 340. Accordingly, there may be shielded the electric field between the base circuit layer 320 and the pixel array layer 340.

The shielding layer 430 may be electrically connected to a second power line PL2, which is one of two or more power lines PL1 to PLm, through a hole in the organic layer 1422. The second power line PL2 may be a power line to which the second driving voltage VSS is applied.

The plurality of power lines PL1 to PLm disposed in the base circuit layer 320 may include the same material as the first source electrode A and first drain electrode B of the gate driving transistor Tg.

The pixel array layer 340 may include a plurality of pixel driving transistors Tp, a plurality of storage capacitors Cst, and a plurality of light emitting devices ED.

The pixel array layer 340 may include a second buffer layer 1430, a second interlayer insulating film 1431, a third interlayer insulating film 1432, a second gate insulating film 1433, a fourth interlayer insulating film 1434, a planarization film 1440, a bank 1450, and a spacer 1451. Here, the planarization film 1440 may include a first planarization film 1441 and a second planarization film 1442.

Each of the plurality of pixel driving transistors Tp may include a second active layer ACT2, a second source electrode D, a second drain electrode E, and a second gate electrode F.

Each of the plurality of storage capacitors Cst may include a first capacitor electrode PLT1 and a second capacitor electrode PLT2.

Each of the plurality of light emitting devices ED may include a pixel electrode PE, a device intermediate layer EL, and a common electrode CE.

The second buffer layer 1430 may be disposed on the shielding layer 430.

The first capacitor electrode PLT1 may be disposed on the second buffer layer 1430, the second interlayer insulating film 1431 may be disposed on the first capacitor electrode PLT1, and the second capacitor electrode PLT2 may be disposed on the second interlayer insulating film 1431.

The first capacitor electrode PLT1 and the second capacitor electrode PLT2 may overlap each other to form a storage capacitor Cst.

The third interlayer insulating film 1432 may be disposed on the second capacitor electrode PLT2.

The second active layer ACT2 may be disposed on the third interlayer insulating film 1432.

The second gate insulating film 1433 may be disposed on the second active layer ACT2, and the second gate electrode F may be disposed on the second gate insulating film 1433. The second gate electrode F may overlap a portion of the second active layer ACT2. An area of the second active layer ACT2 overlapping with the second gate electrode F may be a channel area.

The fourth interlayer insulating film 1434 may be disposed on the second gate electrode F, and the second source electrode E and the second drain electrode D may be disposed on the fourth interlayer insulating film 1434.

The second source electrode E may be electrically connected to a first portion of the second active layer ACT2 through a first hole of the fourth interlayer insulating film 1434, and the second drain electrode D may be electrically connected to a second portion of the second active layer ACT2 through a second hole of the fourth interlayer insulating film 1434. The area between the first and second portions of the second active layer ACT2 may be a channel area.

The planarization film 1440 may be disposed on the second source electrode E and the second drain electrode D. The pixel electrode PE may be disposed on the planarization film 1440, and may be electrically connected to the second source electrode E or the second drain electrode D through a hole in the planarization film 1440.

In the case that the planarization film 1440 includes the first planarization film 1441 and the second planarization film 1442, the first planarization film 1441 may be disposed on the second source electrode E and the second drain electrode D, and a relay electrode RE may be disposed on the first planarization film 1441 and electrically connected to the second source electrode E or the second drain electrode D through a hole in the first planarization film 1441. The second planarization film 1442 may be disposed on the relay electrode RE. The pixel electrode PE may be disposed on the second planarization film 1442, and may be electrically connected to the relay electrode RE through a hole in the second planarization film 1442.

If the subpixel SP has the structure as shown in FIG. 2, since the pixel driving transistor Tp shown in FIG. 14 includes a second source electrode E electrically connected to the pixel electrode PE of the light emitting device ED, the pixel driving transistor Tp shown in FIG. 14 may be the first transistor T1 in FIG. 2.

In the case that the subpixel SP has the structure shown in FIG. 7, since the pixel driving transistor Tp shown in FIG. 14 includes a second source electrode E electrically connected to the pixel electrode PE of the light emitting device ED, the pixel driving transistor Tp shown in FIG. 14 may be the fourth transistor T4 or the sixth transistor T6 in FIG. 7.

The bank 1450 may be disposed on the pixel electrode PE, and may have an opening corresponding to an emission area EA.

The device intermediate layer EL may be disposed on the bank 1450, and may contact the pixel electrode PE at the opening of the bank 1450. The spacer 1451 may be located on the bank 1450 at some point (e.g., a point overlapping the pixel electrode PE or a boundary point of the emission area EA).

The common electrode CE may be disposed on the device intermediate layer EL.

An area where the pixel electrode PE, the device intermediate layer EL, and the common electrode CE overlap without another insulating film may form the emission area EA.

If the light emitting device ED is an organic light emitting device, the device intermediate layer EL may include an emission layer EML disposed only in and near the emission area EA, a first common layer between the anode and the emission layer, and a second common layer between the emission layer and the cathode. Here, the anode may be a pixel electrode PE or a common electrode CE, and the cathode may be a common electrode CE or a pixel electrode PE. The first common layer may include a hole injection layer HIL and a hole transport layer HTL, and the second common layer may include an electron transport layer ETL and an electron injection layer EIL. The hole injection layer may inject holes from the anode to the hole transport layer, the hole transport layer may transport holes to the emission layer, the electron injection layer may inject electrons from the cathode to the electron transport layer, and the electron transport layer may transport electrons to the emission layer. The emission layer of the device intermediate layer EL may be disposed in each subpixel SP, and the first and second common layers of the device intermediate layer EL may be commonly disposed in a plurality of subpixels SP.

The encapsulation layer 250 may be disposed on the pixel array layer 340.

The encapsulation layer 250 may include a first encapsulation layer 1461, a second encapsulation layer 1462, and a third encapsulation layer 1463. For example, the first encapsulation layer 1461 and the third encapsulation layer 1463 may be inorganic layers, and the second encapsulation layer 1462 may be an organic layer.

A first metal GA in the base circuit layer 320 and a second metal GB in the pixel array layer 340 may be electrically connected through the opening of the shielding layer 430.

In addition, the first metal GA in the base circuit layer 320 and the second metal GB in the pixel array layer 340 may be electrically connected through a connection metal GCP separated from the shielding layer 430. Here, the connection metal GCP may include the same material as the shielding layer 430, and may be located in the same layer as the shielding layer 430.

The second metal GB in the pixel array layer 340 may be disposed on the second gate insulating film 1433. The second metal GB may include the same material as the second gate electrode F, and may be located in the same layer.

The first metal GA in the base circuit layer 320 may be disposed on the first interlayer insulating film 1421.

The second metal GB in the pixel array layer 340 may be electrically connected to the first metal GA in the base circuit layer 320 through the holes in the second buffer layer 1430, the second interlayer insulating film 1431, the third interlayer insulating film 1432, the second gate insulating film 1433, the shielding layer 43, and the organic layer 1422.

The first metal GA in the base circuit layer 320 may be a metal which electrically corresponds to the output nodes Nout1a, Nout1b, Nout1 and Nout2 in the base circuit layer 320 of FIGS. 11 and 12.

The second metal GB in the pixel array layer 340 may be a metal which electrically corresponds to the input nodes Nin1 and Nin2 in the pixel array layer 340 of FIGS. 11 and 12. For example, the second metal GB in the pixel array layer 340 may be one of the first scan line SCL1, the second scan line SCL2, the third scan line SCL3, the first emission control line EML1, and the second emission control line EML2.

Referring to FIG. 14, the base circuit layer 320 may include a gate driving transistor Tg including a first active layer ACT1, and the pixel array layer 340 may include a pixel driving transistor Tp including a second active layer ACT2.

The first active layer ACT1 and the second active layer ACT2 may include different semiconductor materials. For example, the first active layer ACT1 may include a silicon-based semiconductor material. The second active layer ACT2 may include an oxide-based semiconductor material.

For example, the silicon-based semiconductor material may include amorphous silicon (a-Si) or a low-temperature polycrystalline silicon (LTPS).

For example, oxide-based semiconductor materials may include indium gallium zinc oxide (IGZO), indium gallium zinc tin oxide (IGZTO), zinc oxide (ZnO), cadmium oxide (CdO), indium oxide (InO), and zinc tin oxide (ZTO), zinc indium tin oxide (ZITO), and may also include a low-temperature polycrystalline oxide (LTPO).

The first active layer ACT1 and/or the second active layer ACT2 may be a single layer or a multi-layer. For example, when the first active layer ACT1 and/or the second active layer ACT2 are the multi-layer, the multilayers may be composed of the same semiconductor material or may be composed of two or more different semiconductor materials.

Referring to FIG. 14, the encapsulation layer 250 and the common electrode CE may overlap with the gate driving circuit 130.

Referring to FIG. 14, the common electrode CE may be an electrode capable of transmitting light. The pixel electrode PE may be a reflective electrode and may overlap with at least a portion of the gate driving circuit 130. Accordingly, the display panel 110 may have a structure capable of top emission.

Referring to FIG. 14, a second driving voltage VSS may be applied to the shielding layer 430 included in the display panel 110 according to one or more example embodiments of the present disclosure.

Referring to FIG. 14, the shielding layer 430 may be electrically connected to the common electrode CE to which the second driving voltage VSS, which is a type of pixel driving voltage, is applied.

The common electrode CE and the shielding layer 430 may be electrically connected through a first connection pattern CP1 and a second connection pattern CP2.

The first connection pattern CP1 may be a metal disposed on the fourth interlayer insulating film 1434. The first connection pattern CP1 may be connected to the shielding layer 430 through the holes in the second buffer layer 1430, the second interlayer insulating film 1431, the third interlayer insulating film 1432, the second gate insulating film 1433, and the fourth interlayer insulating film 1434.

The second connection pattern CP2 may be a metal disposed on the first planarization film 1441. The second connection pattern CP2 may be connected to the first connection pattern CP1 through a hole in the first planarization film 1441.

The first connection pattern CP1 and the second connection pattern CP2 may be electrically connected to the second driving voltage line VSSL disposed in the pixel array layer 340. At least one of the first connection pattern CP1 and the second connection pattern CP2 may be a second driving voltage line VSSL disposed on the pixel array layer 340.

The common electrode CE in the pixel array layer 340 and the second power line PL2 in the base circuit layer 320 may be connected through the first and second connection patterns CP1 and CP2 and the shielding layer 430.

FIG. 15 is another cross-sectional view of the display area DA of a display panel 110 according to one or more example embodiments of the present disclosure.

The display panel 110 of FIG. 15 differs from the display panel 110 of FIG. 14 only in the type of voltage applied to the shielding layer 430, but the other features are the same or substantially the same. Accordingly, the following description will focus on features different from those of the display panel 110 of FIG. 14, and repetitive descriptions may be omitted.

Referring to FIG. 15, a first driving voltage VDD may be applied to the shielding layer 430 included in the display panel 110 according to one or more example embodiments of the present disclosure.

Referring to FIG. 15, the shielding layer 430 may be electrically connected to a third connection pattern CP3 to which the first driving voltage VDD, which is another type of pixel driving voltage, is applied. Here, the third connection pattern CP3 may be a first driving voltage line VDDL for transmitting the first driving voltage VDD or a pattern connected to the first driving voltage line VDDL.

The third connection pattern CP3 may be a metal disposed on the fourth interlayer insulating film 1434. The third connection pattern CP3 may be connected to the shielding layer 430 through the holes in the second buffer layer 1430, the second interlayer insulating film 1431, the third interlayer insulating film 1432, the second gate insulating film 1433, and the fourth interlayer insulating film 1434.

The third connection pattern CP3 may be electrically connected to the first driving voltage line VDDL disposed in the pixel array layer 340, or may be the first driving voltage line VDDL disposed in the pixel array layer 340.

Alternatively, the third connection pattern CP3 may be electrically connected to the source electrode or drain electrode of the pixel driving transistor to which the first driving voltage VDD is applied, among the plurality of pixel driving transistors.

In the case that the subpixel SP has the structure shown in FIG. 7, the third connection pattern CP3 may be the drain electrode or source electrode of the fifth transistor T5 to which the first driving voltage VDD is applied. If the subpixel SP has the structure shown in FIG. 2, the third connection pattern CP3 may be the drain electrode or source electrode of the first transistor T5 to which the first driving voltage VDD is applied.

The shielding layer 430 may be electrically connected to the source electrode or drain electrode of one of the plurality of pixel driving transistors.

Referring to FIG. 15, a first power line PL1 may be disposed within the base circuit layer 320. The first power line PL1 in the base circuit layer 320 may be electrically connected to the shielding layer 430.

Referring to FIG. 15, the third connection pattern CP3 in the pixel array layer 340 may be electrically connected to the first power line PL1 in the base circuit layer 320 through the shielding layer 430.

Among the plurality of pixel driving transistors disposed in the pixel array layer 340, the source electrode or drain electrode of the pixel driving transistor to which the first driving voltage VDD is applied may be electrically connected to the shielding layer 430.

The shielding layer 430 may be electrically connected to the first power line PL1 in the base circuit layer 320.

Among the plurality of pixel driving transistors disposed in the pixel array layer 340, the source electrode or drain electrode of the pixel driving transistor to which the first driving voltage VDD is applied may be electrically connected to the first power line PL1.

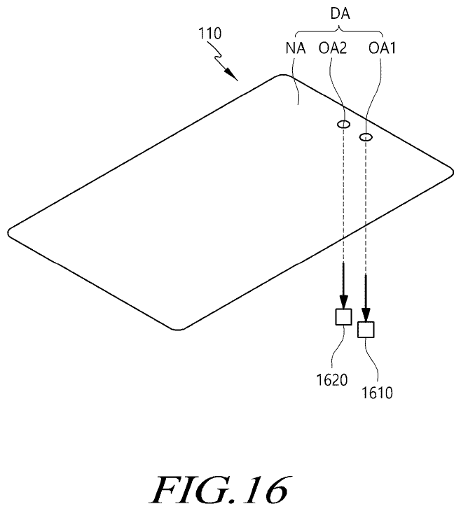

FIG. 16 is a plan view of a display panel 110 according to one or more example embodiments of the present disclosure.

Referring to FIG. 16, the display area DA of the display panel 110 according to one or more example embodiments of the present disclosure may include a general area NA and a first optical area OA1.

The display device 100 according to one or more example embodiments of the present disclosure may include a first optical electronic device 1610 located below a substrate 210 of the display panel 110.

The first optical electronic device 1610 may overlap with the first optical area OA1, and may receive light transmitted through the first optical area OA1 of the display panel 110 to perform a predetermined operation based on the received light.

The first optical area OA1 may have a high-transmission structure to allow light to pass from the front to the back of the display panel 110.

Referring to FIG. 16, the display area DA of the display panel 110 according to one or more example embodiments of the present disclosure may further include a second optical area OA2 which is different from the first optical area OA1.

The display device 100 according to one or more example embodiments of the present disclosure may further include a second optical electronic device 1620 located below the substrate 210 of the display panel 110.

The second optical electronic device 1620 may overlap with the second optical area OA2, and may receive light transmitted through the second optical area OA2 of the display panel 110 to perform a predetermined operation based on the received light.

The second optical area OA2 may have a high-transmission structure to allow light to pass from the front to the back of the display panel 110.

For example, the first optical electronic device 1610 may be a camera (or image sensor), and the second optical electronic device 1620 may be a detection sensor. Here, the detection sensor may include a proximity sensor, an infrared sensor, and/or another sensor.

For example, the first optical electronic device 1610 may perform a determined operation based on light of a first wavelength, and the second optical electronic device 1620 may perform a determined operation based on light of a second wavelength different from the first wavelength. Here, the first wavelength may be a visible light wavelength, and the second wavelength may be an infrared wavelength or an ultraviolet wavelength.

If the display area DA includes both the first optical area OA1 and the second optical area OA2, the structure of the first optical area OA1 and the structure of the second optical area OA2 may be of the same type (e.g., first type or second type), and a structure of one of the first optical area OA1 and the second optical area OA2 may be the first type, and a structure of the other may be the second type.

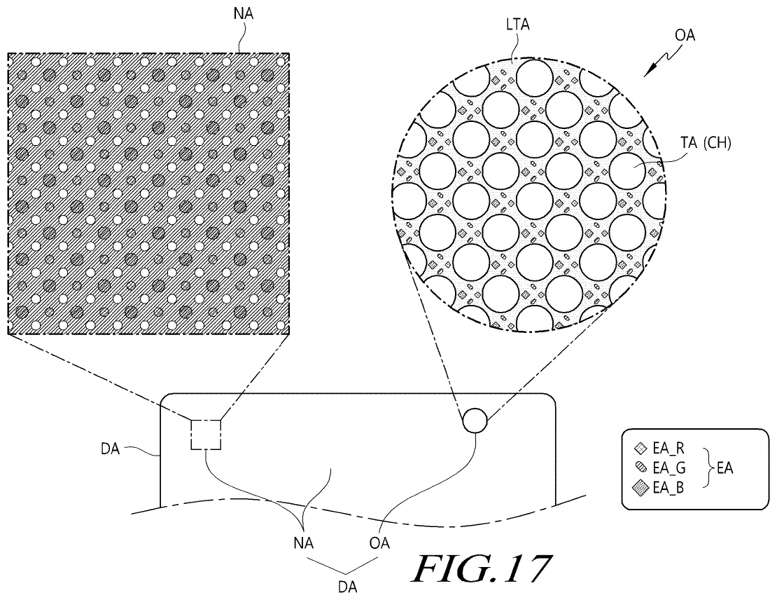

FIG. 17 illustrates a general area NA and an optical area OA1 of a first type included in the display area DA of a display panel 110 according to one or more example embodiments of the present disclosure.

Referring to FIG. 17, the display area DA may include a general area NA and an optical area OA. For example, the optical area OA may have various shapes, such as circular, oval, polygonal, or irregular shapes.

Referring to FIG. 17, a plurality of light emitting device ED and a plurality of subpixel circuits SPC constituting a plurality of subpixels SP may be disposed in the optical area OA. In this way, if a plurality of light emitting devices ED and a plurality of subpixel circuits SPC are disposed in the optical area OA, a structure of the optical area OA may be referred to have a first type.

Referring to FIG. 17, if the structure of the optical area OA is the first type, the optical area OA may include a plurality of transmission areas TA and a low transmission area LTA.

The plurality of transmission areas TA may be areas with high light transmittance or areas capable of transmitting light. The low transmission area LTA may be an area with low light transmittance or an area where light transmission is impossible. The light transmittance of the plurality of transmission areas TA is higher than that of the low transmission area LTA.

The plurality of transmission areas TA in the optical area OA having the first type of structure may also be referred to as a plurality of holes. The first type may be referred to as a hole type.

Referring to FIG. 17, a plurality of subpixels SP may be disposed in the optical area OA having the first type of structure. That is, a plurality of light emitting devices ED and a plurality of subpixel circuits SPC for driving the same may be disposed in the optical area OA having the first type of structure.

Referring to FIG. 17, a plurality of light emitting devices ED may be disposed in the low transmission area LTA within the optical area OA. That is, the low transmission area LTA in the optical area OA may include a plurality of emission areas EA.

Referring to FIG. 17, a plurality of subpixel circuits SPC may be disposed in the low transmission area LTA within the optical area OA. Each of the plurality of subpixel circuits SPC may include a plurality of pixel driving transistors and one or more capacitors. Accordingly, a plurality of pixel driving transistors and one or more capacitors may be disposed in the low transmission area LTA within the optical area OA.

Referring to FIG. 17, some of the plurality of data lines DL disposed on the pixel array layer 340 of the display panel 110 may pass through the optical area OA. Some of the data lines DL passing through the optical area OA may be disposed while avoiding the plurality of transmission areas TA within the optical area OA. Alternatively, some of the data lines DL passing through the optical area OA may be composed of transparent line and may pass through a plurality of transmission areas TA within the optical area OA.

Referring to FIG. 17, some of the plurality of gate lines GL disposed on the pixel array layer 340 of the display panel 110 may pass through the optical area OA. Some of the gate lines GL passing through the optical area OA may be disposed while avoiding the plurality of transmission areas TA within the optical area OA. Alternatively, some of the gate lines GL passing through the optical area OA may be composed of transparent line and may pass through a plurality of transmission areas TA within the optical area OA.

Referring to FIG. 17, some of the plurality of pixel driving voltage lines VDDL, VSSL, VARL and VREFL disposed on the pixel array layer 340 of the display panel 110 may pass through the optical area OA. Some of the pixel driving voltage lines VDDL, VSSL, VARL and VREFL passing through the optical area OA may be disposed while avoiding the plurality of transmission areas TA within the optical area OA. Alternatively, some of the pixel driving voltage lines VDDL, VSSL, VARL and VREFL passing through the optical area OA may be composed of transparent line and may pass through a plurality of transmission areas TA within the optical area OA.

Referring to FIG. 17, the plurality of light emitting devices ED and the plurality of subpixel circuits SPC may be not disposed in the plurality of transmission areas TA.

Referring to FIG. 17, in the optical area OA, the light transmittance of the low transmission area LTA may be lower than the light transmittance of the transmission area TA. The light transmittance of the low transmission area LTA may be greater than or equal to the light transmittance of the general area NA.

Referring to FIG. 17, the arrangement of the emission areas EA in the optical area OA may be the same as the arrangement of the emission areas EA in the general area NA.

The area of each of the plurality of emission areas EA included in the optical area OA may be the same as the area of each of the plurality of emission areas EA included in the general area NA, or may be different from the area of each of the plurality of emission areas EA included in the general area NA within a predetermined range.

The areas of each of the plurality of emission areas EA included in the optical area OA may be the same or different within a predetermined range.

The common electrode CE may be commonly disposed in the general area NA and the optical area OA.

Optionally, a portion of the common electrode CE disposed in the optical area OA may have a plurality of holes CH. The plurality of holes CH formed in the common electrode CE may positionally correspond to the transmission areas TA in the optical area OA.

Alternatively, a portion of the common electrode CE disposed in the optical area OA may not have a hole CH.

Since the optical area OA includes a plurality of transmission areas TA, the optical area OA may have a light transmittance higher than that of the general area NA.

For example, the plurality of emission areas EA disposed in the optical area OA may include a first color emission area emitting light of a first color, a second color emission area emitting light of a second color, and a third color emission area emitting light of a third color.

At least one of the first color emission area, the second color emission area, and the third color emission area may have an area different from the others.

The first color, second color, and third color may be different colors and may be various colors. For example, the first color, second color, and third color may include red, green, and blue.

For example, the first color is red, the second color is green, and the third color is blue. However, it is not limited to this.

If the first color is red, the second color is green, and the third color is blue, among the area of a red emission area EA_R, the area of a green emission area EA_G, and the area of a blue emission area EA_B, the area of the blue emission area EA_B may be the largest.

The light emitting device ED disposed in the red emission area EA_R may include an emission layer which emits red light. The light emitting device ED disposed in the green emission area EA_G may include an emission layer which emits green light. The light emitting device ED disposed in the blue emission area EA_B may include an emission layer which emits blue light.

Among the emission layer emitting red light, the emission layer emitting green light and the emission layer emitting blue light, organic substances contained in the emission layer emitting blue light may be the most susceptible to material deterioration.

Since the area of the blue emission area EA_B is designed to be the largest, the current density supplied to the light emitting device ED disposed in the blue emission area EA_B may be the lowest. Therefore, the degree of deterioration of the light emitting device ED disposed in the blue emission area EA_B may become similar to the degree of deterioration of the light emitting device ED disposed in the red emission area EA_R and the light emitting device ED disposed in the green emission area EA_G.

Therefore, there may be eliminated or reduced the deterioration variation between the light emitting device ED disposed in the red emission area EA_R, the light emitting device ED disposed in the green emission area EA_G, and the light emitting device ED disposed in the blue emission area EA_B, thereby improving image quality. In addition, since there may be eliminated or reduced the deterioration variation between light emitting device ED disposed in the red emission area EA_R, the light emitting device ED disposed in the green emission area EA_G, and the light emitting device ED disposed in the blue emission area EA_B, there may provide the effect of reducing the lifespan variation between the light emitting device ED disposed in the red emission area EA_R, the light emitting device ED disposed in the green emission area EA_G, and the light emitting device ED disposed in the blue emission area EA_B.

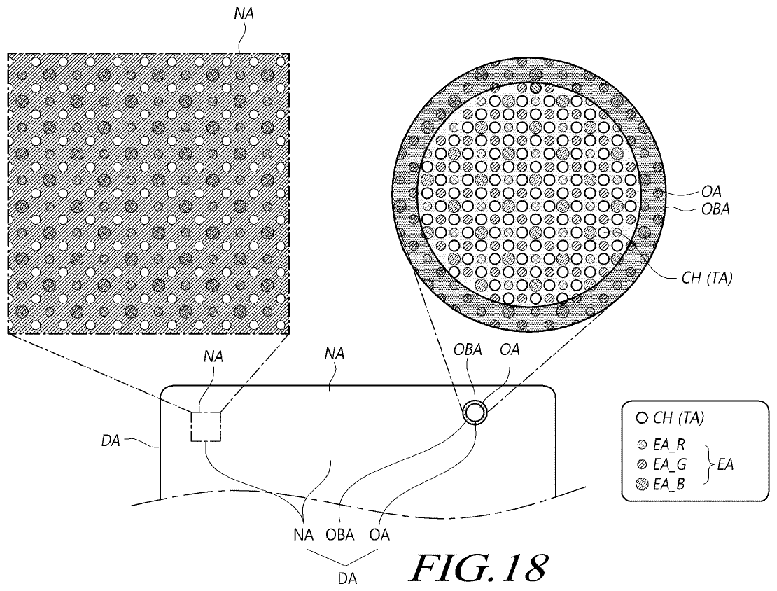

FIG. 18 illustrates a general area and a second type of optical area OA included in the display area DA of a display panel 110 according to one or more example embodiments of the present disclosure.

Referring to FIG. 18, the display area DA may include an optical area OA and a general area NA surrounding the optical area OA.

Referring to FIG. 18, among the plurality of light emitting devices ED and the plurality of subpixel circuits SPC constituting the plurality of subpixels SP, only the plurality of light emitting devices ED may be disposed in the optical area OA, and the plurality of subpixel circuits SPC may not be arranged in the optical area OA. In this way, if only a plurality of light emitting devices ED among the plurality of light emitting devices ED and the plurality of subpixel circuits SPC are disposed in the optical area OA, a structure of this optical area OA may be referred to as a second type.

Referring to FIG. 18, when the optical area OA has a second type structure, an optical bezel area OBA may be disposed outside the optical area OA. The optical bezel area OBA may also be considered as part of the general area NA.

If the optical area OA is the second type, the display area DA may include an optical area OA, a general area NA located outside the optical area OA, and an optical bezel area OBA which is an area between the optical area OA and the general area NA.

The optical area OA may include a plurality of emission areas EA and at least one transmission area TA. All areas excluding the plurality of emission areas EA in the optical area OA may be a transmission area TA. Alternatively, an area excluding the plurality of emission areas EA from the optical area OA may include a plurality of transmission areas TA.

A plurality of light emitting devices ED may be disposed in the optical area OA having the second type of structure. The plurality of subpixel circuits SPC for driving the plurality of light emitting devices ED arranged in the optical area OA having the second type structure may be not disposed in the optical area OA.

A plurality of subpixel circuits SPC for driving a plurality of light emitting devices ED disposed in the optical area OA having the second type of structure may be disposed in the optical bezel area OBA.

A plurality of light emitting devices ED and a plurality of subpixel circuits SPC may be disposed in the optical bezel area OBA, and may be disposed in the optical area OA having a second type of structure. A plurality of subpixel circuits SPC for driving a plurality of light emitting devices ED may also be further disposed.

Meanwhile, one subpixel circuit SPC disposed in the optical bezel area OBA may drive one light emitting device ED disposed in the optical area OA. Alternatively, one subpixel circuit SPC disposed in the optical bezel area OBA may drive two or more light emitting devices ED disposed in the optical area OA.

As described above, when the optical area OA has a second type of structure, the light emitting devices ED disposed in the optical area OA is required to be driven by a subpixel circuit SPC disposed in the optical bezel area OBA. To this end, if the optical area OA has a second type of structure, an anode for configuring the light emitting device ED disposed in the optical area OA may extend to the optical bezel area OBA to be electrically connected to the subpixel circuit SPC located in the optical bezel area OBA. In this sense, the second type may also be referred to as an anode extension type.

Referring to FIG. 18, the optical bezel area OBA may be an area located outside the optical area OA. The general area NA may be an area located outside the optical bezel area OBA. The optical bezel area OBA may be disposed between the optical area OA and the general area NA.

For example, the optical bezel area OBA may be disposed only outside a partial border of the optical area OA, or may be arranged outside the entire border of the optical area OA.

In the case that the optical bezel area OBA is disposed outside the entire border of the optical area OA, the optical bezel area OBA may have a ring shape surrounding the optical area OA. For example, the optical area OA may have various shapes, such as circular, oval, polygonal, or irregular shapes. The optical bezel area OBA may have various ring shapes (e.g., a circular ring shape, an elliptical ring shape, a polygonal ring shape, an irregular ring shape, or another shape) surrounding the optical area OA having various shapes.

Referring to FIG. 18, the display area DA may include a plurality of emission areas EA. Since the optical area OA, the optical bezel area OBA and the general area NA are areas included in the display area DA, each of the optical area OA, the optical bezel area OBA and the general area NA may include a plurality of emission areas EA.

Referring to FIG. 18, the optical area OA is a transmission area, and is required to have high transmittance. To this end, the portion of the common electrode CE disposed in the optical area OA may have a plurality of holes CH. That is, in the optical area OA, the common electrode CE may include a plurality of cathode holes CH.

Referring to FIG. 18, the portion of the common electrode CE disposed in the general area NA may not have a hole CH. That is, in the general area NA, the common electrode CE may not include the hole CH.

In addition, the portion of the common electrode CE disposed in the optical bezel area OBA may not include a hole CH. That is, in the optical bezel area OBA, the common electrode CE may not include the hole CH.

A plurality of holes CH formed in a portion of the common electrode CE disposed in the optical area OA may also be referred to as a plurality of transmission areas TA or a plurality of openings. One hole CH may have various shapes such as circular, oval, polygonal, or irregular shape.

The optical area OA of FIGS. 17 and 18 may be one of the first optical area OA1 and the second optical area OA2 of FIG. 16.

The optical area OA of FIGS. 17 and 18 may be an area which overlaps with an optical electronic device, and may be a transmission area through which light necessary for the operation of the optical electronic device can be transmitted. Here, the light passing through the optical area OA may include light in a single wavelength band or light in various wavelength bands. For example, light passing through the optical area OA may include one or more of visible light, infrared light, or ultraviolet light.

The optical electronic device may receive light passing through the optical area OA and perform a predetermined operation using the received light. Here, the light received by the optical electronic device through the optical area OA may include at least one of visible light, infrared light, or ultraviolet light.

For example, if the optical electronic device is a camera, the light transmitted through the optical area OA and utilized by the optical electronic device may include visible light. For another example, if the optical electronic device is an infrared-based sensor, the light transmitted through the optical area OA and utilized by the optical electronic device may include infrared light (also referred to as infrared ray).

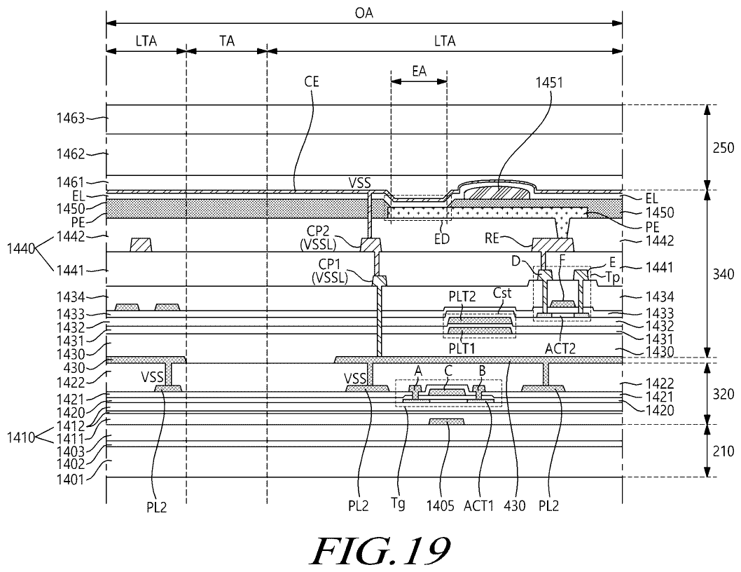

FIG. 19 is a cross-sectional view of an optical area OA within a display area DA of a display panel 110 according to one or more example embodiments of the present disclosure. However, the structure of the optical area OA in FIG. 19 is of the first type.

The display panel 110 of FIG. 19 may have the same vertical structure, or substantially the same vertical structure, as the display panel 110 of FIG. 14. Accordingly, the following description will focus on features different from those of the display panel 110 of FIG. 14, and repetitive descriptions may be omitted.

The cross-sectional view of FIG. 14 may represent a vertical structure of the general area NA, and the cross-sectional view of FIG. 19 may represent a vertical structure of the optical area OA.

Referring to FIG. 19, the optical area OA included in the display area DA may include at least one transmission area TA and a low transmission area LTA.

A plurality of subpixels SP may be disposed in the optical area OA. That is, a light emitting device ED and a pixel driving transistor Tp included in the subpixel circuit SPC for driving the same may be disposed in the optical area OA.

The light emitting device ED may be disposed in the low transmission area LTA within the optical area OA. That is, the low transmission area LTA in the optical area OA may include the emission area EA.

The pixel driving transistor Tp included in the subpixel circuit SPC may be disposed in the low transmission area LTA within the optical area OA.

Referring to FIG. 19, a gate driving circuit 130 may be disposed over the entire display area DA, but may not overlap with at least one transmission area TA in the optical area OA.

That is, the gate driving circuit 130 may be disposed in an area which is not at least one transmission area TA, and the gate driving circuit 130 may not disposed in at least one transmission area TA. Accordingly, the light transmittance of at least one transmission area TA in the optical area OA may be increased.

Referring to FIG. 19, a shielding layer 430 may be disposed so as not to overlap with at least one transmission area TA. That is, the shielding layer 430 may be disposed in an area that is not at least one transmission area TA, and the shielding layer 430 may not disposed in at least one transmission area TA.

A portion of the shielding layer 430 disposed in the optical area OA may include at least one opening. At least one opening formed in the shielding layer 430 in the optical area OA may positionally correspond to at least one transmission area TA in the optical area OA. Accordingly, the light transmittance of at least one transmission area TA in the optical area OA may be increased.

Various examples and aspects of the present disclosure are described below. These are provided as examples, and do not limit the scope of the present disclosure.

A display device according to one or more example embodiments of the present disclosure may include a substrate, a pixel array layer located on the substrate and including a plurality of subpixels disposed in a display area where an image is displayed, and a base circuit layer located between the substrate and the pixel array layer and including a gate driving circuit disposed over the entire display area.

The base circuit layer may include two or more power lines which are disposed in the display area, and to which two or more common pixel driving voltages supplied to the pixel array layer are applied.

A display device according to one or more example embodiments of the present disclosure may further include a shielding layer located between the base circuit layer and the pixel array layer.

The shielding layer may be electrically connected to a metal disposed on the pixel array layer.

For example, the shielding layer may be electrically connected to a source electrode or a drain electrode of one of a plurality of pixel driving transistors disposed in the pixel array layer, or may be electrically connected to a first driving voltage line disposed on the pixel array layer. Here, the first driving voltage VDD may be applied to the source electrode or drain electrode of one pixel driving transistor. The first driving voltage VDD, which is another type of pixel driving voltage, may be applied to the first driving voltage line.

As another example, the shielding layer may be electrically connected to a common electrode among a pixel electrode and a common electrode included in the light emitting device disposed in the pixel array layer, or may be electrically connected to a second driving voltage line disposed in the pixel array layer. Here, a second driving voltage VSS, which is a type of pixel driving voltage, may be applied to the common electrode or the second driving voltage line.

The shielding layer may be electrically connected to a metal located in the base circuit layer.

The base circuit layer may include two or more power lines which are disposed in the display area, and to which two or more common pixel driving voltages supplied to the pixel array layer are applied.

The shielding layer may be electrically connected to one of the two or more power lines.

As an example, the shielding layer may be electrically connected to a first power line to which the first driving voltage VDD is applied among two or more power lines.

As another example, the shielding layer may be electrically connected to a second power line to which a second driving voltage VSS is applied among two or more power lines.

The shielding layer may electrically connect a metal located in the pixel array layer and a metal located in the base circuit layer.

The base circuit layer may include a gate driving transistor including a first active layer, the pixel array layer may include a pixel driving transistor including a second active layer, and the first active layer and the second active layer may include different semiconductor materials.

The base circuit layer may include a plurality of unit areas disposed over the entire display area.

Each of the plurality of unit areas may include a plurality of subcircuit areas and a plurality of power line areas. The plurality of subcircuit areas and the plurality of power line areas may be arranged alternately with each other,

The plurality of power line areas may include a plurality of power lines to which a voltage having a constant voltage level is applied.

The plurality of subcircuit areas may include a plurality of subcircuits included in the gate driving circuit. The plurality of subcircuits may be configured to output different types of gate signals.

The width of each of the plurality of power line areas may be the same, at least one of the plurality of power lines included in each of the plurality of power line areas may have a width different from the others, and at least one of the plurality of subcircuit areas may have a width different from the others.

The base circuit layer may include an organic layer disposed on a plurality of gate driving transistors included in the gate driving circuit.

An upper surface of the organic layer may have a smaller step than the back surface of the organic layer, and the organic layer may have a thickness greater than the gate insulating film between the active layer and the gate electrode of each of the plurality of gate driving transistors.

A display device according to one or more example embodiments of the present disclosure may further include an encapsulation layer located on the pixel array layer.

The pixel array layer may include a plurality of light emitting devices and a plurality of pixel driving transistors, and each of the plurality of light emitting devices may include a pixel electrode and a common electrode.

The encapsulation layer and the common electrode may overlap with the gate driving circuit. The pixel electrode may be a reflective electrode and may overlap at least a portion of the gate driving circuit.

The display area may include a general area and an optical area. The general area may include a plurality of emission areas, and the optical area may include at least one transmission area.

The gate driving circuit may be disposed over the entire display area, but may be disposed so as not to overlap with at least one transmission area in the optical area.

The shielding layer located between the base circuit layer and the pixel array layer may be disposed so as not to overlap at least one transmission area.

A display device according to one or more example embodiments of the present disclosure may further include an optical electronic device located below the substrate and overlapping with the optical area.

A display panel according to one or more example embodiments of the present disclosure may include a substrate, a pixel array layer located on the substrate and including a plurality of subpixels disposed in a display area where an image is displayed, a base circuit layer located between the substrate and the pixel array layer and on, at or in which a gate driving circuit is disposed, and a shielding layer located between the base circuit layer and the pixel array layer.

The base circuit layer may include an organic layer disposed on a gate driving transistor included in the gate driving circuit.

The base circuit layer may include two or more power lines to which two or more common pixel driving voltages supplied to the pixel array layer are applied.

The shielding layer may electrically connect a metal disposed in the pixel array layer and a metal disposed in the base circuit layer.

A display apparatus according to one or more example embodiments of the present disclosure may include a substrate, a pixel array layer disposed on the substrate and including a plurality of subpixels disposed in a display area in which an image is to be displayed, and a base circuit layer disposed between the substrate and the pixel array layer and including a driving circuit. The plurality of subpixels may include pixel driving transistors. The driving circuit may include transistors. One or more of the transistors in the base circuit layer may be coupled to respective one or more of the pixel driving transistors in the pixel array layer.

The base circuit layer may include one or more power lines coupled to at least one of the plurality of subpixels. The driving circuit of the base circuit layer may include gate driving transistors.

In one or more examples, the display apparatus may include, or may be, a display device. In one or more examples, the display apparatus may include, or may be, a display panel. In one or more examples, the display apparatus may include, or may be, a device having electronic and optical components.

In one or more examples, the driving circuit may include, or may be, a gate driving circuit.

According to the one or more example embodiments of the present disclosure, there may provide a display panel and a display device in which a gate driving circuit is arranged over the entire display area. Accordingly, it is possible to significantly reduce a bezel size of the display panel.

According to the one or more example embodiments of the present disclosure, there may provide a display panel and a display device in which a gate driving circuit is arranged to overlap a pixel array layer in a vertical direction, thereby significantly reducing a bezel size of the display panel.

According to the one or more example embodiments of the present disclosure, there may provide a display panel and a display device having a structure capable of shielding an electric field between a base circuit layer where a gate driving circuit is disposed and a pixel array layer where the subpixel are disposed. Accordingly, it is possible to eliminate unnecessary electrical influence between the base circuit layer and the pixel array layer.

According to the one or more example embodiments of the present disclosure, there may provide a display panel and a display device in which a gate driving circuit and various power lines are disposed in a display area. Accordingly, an extremely narrow bezel structure of the display panel may be possible.

According to one or more example embodiments of the present disclosure, the base circuit layer on which the gate driving circuit and various power lines are arranged may be arranged to overlap the pixel array layer in the vertical direction, so that a length of a path through which the gate signal output from the gate driving circuit is supplied to the pixel array layer can be shortened, and a length of a path through which a power (e.g., pixel driving voltage) output from various power lines is supplied to the pixel array layer can be shortened. Accordingly, it is possible to reduce the metal used in the supply path, and thus is possible to reduce the weight of display panels and display devices.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device, comprising:
a substrate;
a pixel array layer located on the substrate and including a plurality of subpixels disposed in a display area where an image is to be displayed; and
a base circuit layer located between the substrate and the pixel array layer and including a gate driving circuit disposed over the entire display area.

2. The display device of claim 1, wherein the base circuit layer comprises two or more power lines which are disposed in the display area, and to which two or more common pixel driving voltages to be supplied to the pixel array layer are for being applied.

3. The display device of claim 1, further comprising a shielding layer located between the base circuit layer and the pixel array layer.

4. The display device of claim 3, wherein the shielding layer is electrically connected to a metal disposed on the pixel array layer.

5. The display device of claim 3, wherein the shielding layer is electrically connected to a source electrode or a drain electrode of one of a plurality of pixel driving transistors disposed in the pixel array layer, or is electrically connected to a first driving voltage line disposed on the pixel array layer.

6. The display device of claim 3, wherein each of the plurality of subpixels comprises a light emitting device including a pixel electrode and a common electrode, and
wherein the shielding layer is electrically connected to the common electrode among the pixel electrodes and common electrodes included in the light emitting device disposed in the pixel array layer, or is electrically connected to a second driving voltage line disposed in the pixel array layer.

7. The display device of claim 3, wherein the shielding layer is electrically connected to a metal located in the base circuit layer.

8. The display device of claim 3, wherein the base circuit layer comprises two or more power lines which are disposed in the display area, and to which two or more common pixel driving voltages supplied to the pixel array layer are applied, and
wherein the shielding layer is electrically connected to one of the two or more power lines.

9. The display device of claim 3, wherein the shielding layer electrically connects a metal located in the pixel array layer and a metal located in the base circuit layer.

10. The display device of claim 1, wherein the base circuit layer comprises a gate driving transistor including a first active layer, and the pixel array layer comprises a pixel driving transistor including a second active layer,
wherein the first active layer and the second active layer include different semiconductor materials.

11. The display device of claim 1, wherein the base circuit layer comprises a plurality of unit areas disposed over the entire display area,
wherein each of the plurality of unit areas comprises a plurality of subcircuit areas and a plurality of power line areas, and the plurality of subcircuit areas and the plurality of power line areas are arranged alternately with each other,
wherein the plurality of power line areas comprise a plurality of power lines to which a voltage having a constant voltage level is for being applied, and
wherein the plurality of subcircuit areas comprise a plurality of subcircuits included in the gate driving circuit, and the plurality of subcircuits are configured to output different types of gate signals.

12. The display device of claim 1, wherein the base circuit layer comprises an organic layer disposed on a plurality of gate driving transistors included in the gate driving circuit.

13. The display device of claim 1, wherein the display area comprises a general area and an optical area,
wherein the general area includes a plurality of emission areas,
wherein the optical area includes at least one transmission area, and
wherein the gate driving circuit is disposed over the entire display area, but is disposed so as not to overlap with the at least one transmission area in the optical area.

14. The display device of claim 13, further comprising a shielding layer located between the base circuit layer and the pixel array layer and disposed not to overlap with the at least one transmission area.

15. A display panel, comprising:
a substrate;
a pixel array layer located on the substrate and including a plurality of subpixels disposed in a display area where an image is to be displayed;
a base circuit layer located between the substrate and the pixel array layer and on or at which a gate driving circuit is disposed; and
a shielding layer located between the base circuit layer and the pixel array layer.

16. The display panel of claim 15, wherein the base circuit layer comprises an organic layer disposed on a gate driving transistor included in the gate driving circuit.

17. The display panel of claim 15, wherein the base circuit layer comprises two or more power lines to which two or more common pixel driving voltages to be supplied to the pixel array layer are for being applied.

18. The display panel of claim 17, wherein the shielding layer electrically connects a metal disposed in the pixel array layer and a metal disposed in the base circuit layer.

19. A display apparatus, comprising:
a substrate;
a pixel array layer disposed on the substrate and including a plurality of subpixels disposed in a display area in which an image is to be displayed; and
a base circuit layer disposed between the substrate and the pixel array layer and including a driving circuit,
wherein:
the plurality of subpixels include pixel driving transistors;
the driving circuit includes transistors; and
one or more of the transistors in the base circuit layer are coupled to respective one or more of the pixel driving transistors in the pixel array layer.

20. The display apparatus of claim 19, wherein:
the base circuit layer includes one or more power lines coupled to at least one of the plurality of subpixels; and
the driving circuit of the base circuit layer includes gate driving transistors.
